(19) United States
(12) Patent Application Publication
(10) Pub. No.: US 2012/0021588 A1
(43) Pub. Date: Jan. 26, 2012

(54) METHOD FOR MANUFACTURING SOI SUBSTRATE AND SEMICONDUCTOR DEVICE

(75) Inventors: Shinya HASEGAWA, Ebina (JP); Atsuo ISOBE, Atsugi (JP); Motomu KURATA, Isehara (JP)

(73) Assignee: SEMICONDUCTOR ENERGY LABORATORY CO., LTD., Atsugi (JP)

(21) Appl. No.: 13/184,591

(22) Filed: Jul. 18, 2011

(30) Foreign Application Priority Data
Jul. 23, 2010 (JP) 2010-165811

(51) Int. Cl. H01L 21/265

(52) U.S. Cl. 438/458; 257/E21.334

(57) ABSTRACT

One object is to provide excellent electric characteristics of an end portion of a single crystal semiconductor layer having a tapered shape. An embrittled region is formed in a single crystal semiconductor substrate by irradiating the single crystal semiconductor substrate with accelerated ions. Then, the single crystal semiconductor substrate and a base substrate are bonded to each other with an insulating film interposed therebetween and a first single crystal semiconductor layer is formed over the base substrate with the insulating film interposed therebetween by separating the single crystal semiconductor substrate at the embrittled region. After that, a second single crystal semiconductor layer having a tapered end portion is formed by performing dry etching on the first single crystal semiconductor layer, and etching is performed on the end portion of the second single crystal semiconductor layer in a state where a potential on the base substrate side is a ground potential.

### BACKGROUND OF THE INVENTION

1. Field of the Invention

The present invention relates to a silicon-on-insulator (SOI) substrate having a so-called SOI structure in which a single crystal semiconductor layer is provided over an insulating surface, a method manufacturing thereof, a semiconductor device having the SOI substrate, and a manufacturing method thereof.

2. Description of the Related Art

In recent years, instead of a bulk silicon wafer, the use of an SOI substrate where a single crystal semiconductor layer is provided over an insulating surface has been considered. Because parasitic capacitance generated by a drain of a transistor and a substrate can be reduced by use of an SOI substrate, SOI substrates are attracting attention as substrates which improve performance of semiconductor integrated circuits.

As an example of a method for manufacturing an SOI substrate, a hydrogen ion implantation separation method is known.

For example, in the hydrogen ion implantation separation method disclosed in Patent Document 1, hydrogen ions are implanted into a silicon wafer to form a microbubble layer in the silicon wafer and separation is caused using the microbubble layer as a cleavage plane by heat treatment, and an SOI layer is formed on another silicon wafer. Further, Patent Document 1 discloses that, after an oxide film is formed in an SOI layer by heat treatment in an oxidizing atmosphere, the oxide film is removed, and a damaged layer remaining on the surface of the SOI layer or surface roughness is removed by heat treatment in a reducing atmosphere.

Patent Document 2 discloses that, vapor-phase etching is performed on an SOI layer obtained by a hydrogen ion implantation separation method, with the use of plasma generated by applying a high frequency from the high-frequency power source to electrodes which are provided above and below the SOI layer so that the SOI layer is interposed therebetween, in order to remove crystal defects on a cleavage plane which is a surface of the SOI layer and make the thickness of the SOI layer uniform, so that a damaged layer on a cleavage plane of the SOI layer is removed.

Further, manufacturing a semiconductor device using a transistor formed over a substrate having an insulating surface such as glass has been considered. In the transistor, a part of an island-shaped semiconductor layer provided over a substrate having an insulating surface is used as a channel formation region.

FIGS. 14A to 14D illustrate an example of a structure of a transistor including the island-shaped semiconductor layer. FIG. 14A is a top view of the transistor. FIG. 14B is a cross-sectional view taken along the broken line joining A1 and B1 in FIG. 14A, and FIG. 14C is a cross-sectional view taken along the broken line joining A2 and B2 in FIG. 14A. Further, FIG. 14D is an enlarged view of an end portion of the semiconductor layer in FIG. 14C.

As illustrated in FIGS. 14A to 14D, in the transistor, an insulating film 1431 serving as a base film is formed over a substrate 1430, and a semiconductor layer 1432 including a channel formation region 1432a and impurity regions 1432b and 1432c serving as a source region or a drain region is formed over the insulating film 1431. Then, a gate insulating film 1433 is formed over the semiconductor layer 1432 and the insulating film 1431, and a gate electrode 1434 is formed over the gate insulating film 1433.

In a step of forming the transistor illustrated in FIGS. 14A to 14D, in the case where the gate insulating film 1433 is formed over the semiconductor layer 1432 which is selectively etched, like films 1433a and 1433b (see FIG. 14D), the thickness of the gate insulating film 1433 becomes uneven, resulting in poor coverage with the gate insulating film 1433, due to the step in the end portion 1425 (see FIG. 14C) of the semiconductor layer 1432. In a section where the thickness of the gate insulating film 1433 is thin, the electric field strength of the gate voltage increases, and this adversely affects the withstand voltage and reliability of the transistor.

In order to improve poor coverage with the gate insulating film 1433 caused by the step of the end portion 1425 of the semiconductor layer 1432, Patent Document 3 discloses that an end portion of the semiconductor layer has a tapered shape.

In a manufacturing process of a transistor disclosed in Patent Document 3, a polycrystalline silicon layer is etched using a photoresist pattern as a mask, whereby a semiconductor layer including an end portion having a taper angle which is less than or equal to 80° is formed. Then, a gate insulating film covering the semiconductor layer is formed. The semiconductor layer is formed to have an end portion having a tapered shape, whereby a phenomenon in which a gate insulating film on a side of the semiconductor layer has a small thickness is reduced and the withstand voltage characteristics of the gate insulating film is improved.

Further, Patent Document 3 discloses that etching of a polycrystalline silicon layer is performed using dry etching which enable uniform etching and little loss of line width caused by etching.

### REFERENCE

[Patent Document 1] Japanese Published Patent Application No. 2000-124092
[Patent Document 2] Japanese Published Patent Application No. H11-102848
[Patent Document 3] Japanese Published Patent Application No. 2005-167207

### SUMMARY OF THE INVENTION

When the single crystal semiconductor layer having a tapered end portion is formed by dry etching, plasma damage or contamination caused by the dry etching occurs in the vicinity of the surface of the end portion of the single crystal semiconductor layer.

Further, the above described single crystal semiconductor layer is used in a transistor, poor characteristics such as change in the interface state between the single crystal semiconductor layer and the insulating film, or the like occur.

Therefore, it is an object of one embodiment of the present invention to provide an SOI substrate in which an end portion of a single crystal semiconductor layer having a tapered shape has favorable characteristics, and a manufacturing method thereof.

Further, it is an object of one embodiment of the present invention to provide a transistor having excellent electric characteristics and high reliability, with the use of an SOI substrate in which an end portion of a single crystal semiconductor layer having a tapered shape has favorable characteristics, and a manufacturing method thereof.

According to one embodiment of the present invention, an embrittled region is formed in a single crystal semiconductor substrate by irradiating the single crystal semiconductor substrate with accelerated ions. Then, the single crystal semiconductor substrate and a base substrate are bonded to each other with an insulating film interposed therebetween; and a first single crystal semiconductor layer is formed over the base substrate with the insulating film interposed therebetween by separating the single crystal semiconductor substrate at the embrittled region. After that, a second single crystal semiconductor layer having a tapered end portion is formed by performing dry etching on the first single crystal semiconductor layer; and etching is performed on the end portion of the second single crystal semiconductor layer in a state where a potential on the base substrate side is a ground potential.

Further, according to one embodiment of the present invention, an oxide film is formed on a surface of a single crystal semiconductor substrate; an embrittled region is formed in the single crystal semiconductor substrate with the oxide film interposed therebetween by irradiating the single crystal semiconductor substrate with accelerated ions. Then, the single crystal semiconductor substrate and a base substrate are bonded to each other with the oxide film and a nitrogen-containing layer interposed therebetween; and a first single crystal semiconductor layer is formed over the base substrate with the oxide film and the nitrogen-containing layer interposed therebetween by separating the single crystal semiconductor substrate at the embrittled region. After that, a second single crystal semiconductor layer having a tapered end portion is formed by performing dry etching on the first single crystal semiconductor layer; and etching is performed on the end portion of the second single crystal semiconductor layer in a state where a potential on the base substrate side is a ground potential.

In the above, it is preferable that a mask pattern be formed over the first single crystal semiconductor layer and the dry etching and the etching in which a potential on the base substrate side is a ground potential be performed using the mask pattern.

In the above, the etching in which the potential on the base substrate side is a ground potential is preferably performed using a gas containing chlorine, carbon tetrafluoride or a gas containing fluorine as an etching gas.

In the above, an end portion of the second single crystal semiconductor layer has preferably a tapered shape having a taper angle greater than or equal to 30° and less than 90°.

In the above, an end portion of the second single crystal semiconductor layer has preferably a tapered shape having a taper angle greater than or equal to 30° and less than or equal to 50°.

In the above, the dry etching is preferably performed using a gas containing chlorine, a gas containing fluorine, trifluoromethane, hydrogen bromide, or any of these gases to which oxygen is added as an etching gas.

Note that, in this specification, a “single crystal” refers to a crystal in which, when a certain crystal axis is focused, the direction of the crystal axis is oriented in the same direction in any portion of a sample and which has no crystal grain boundary between crystals. Note that, in this specification, the single crystal includes a crystal in which the direction of crystal axes is uniform as described above and which has no crystal grain boundary even when it includes a crystal defect or a dangling bond.

Note that, in this specification, the semiconductor device means a general device that can operate by utilizing semiconductor characteristics. For example, electro-optical devices (including display devices), semiconductor circuits, and electric appliances are all included in the category of the semiconductor device.

In addition, in this specification, a display device includes a light-emitting device and a liquid crystal display device in its category. A light-emitting device includes a light-emitting element, and a liquid crystal display device includes a liquid crystal element. The category of a light-emitting element includes an element whose luminance is controlled by current or voltage, and specifically includes an inorganic electroluminescent (EL) element, an organic EL element, and the like.

Further, in this specification, the etching performed in the state where the electric power applied to the lower electrode (on the bias side) is set to 0 W and the potential on the base substrate side is a ground potential is also referred to as an etching in which a substrate bias is not applied.

According to one embodiment of the present invention, an SOI substrate in which an end portion of a single crystal semiconductor layer having a tapered shape has favorable characteristics, and a manufacturing method thereof, can be provided.

Further, according to one embodiment of the present invention, a transistor having excellent electric characteristics, with the use of an SOI substrate in which an end portion of a single crystal semiconductor layer having a tapered shape has favorable characteristics, and a manufacturing method thereof, can be provided.

### BRIEF DESCRIPTION OF THE DRAWINGS

FIGS. 1A to 1F illustrate a method for manufacturing an SOI substrate according to one embodiment of the present invention.

FIGS. 2A to 2C illustrate a method for manufacturing an SOI substrate according to one embodiment of the present invention.

FIGS. 3A to 3D illustrate a method for manufacturing an SOI substrate according to one embodiment of the present invention.

FIGS. 4A to 4G illustrate a method for manufacturing an SOI substrate according to one embodiment of the present invention.

FIGS. 5A to 5C illustrate a method for manufacturing an SOI substrate according to one embodiment of the present invention.

FIGS. 6A to 6D illustrate a method for manufacturing an SOI substrate according to one embodiment of the present invention.

FIGS. 7A to 7C illustrate a method for manufacturing a semiconductor device according to one embodiment of the present invention.

FIGS. 8A to 8D illustrate a method for manufacturing a semiconductor device according to one embodiment of the present invention.

FIGS. 9A and 9B illustrate a method for manufacturing a semiconductor device according to one embodiment of the present invention.

FIGS. 10A to 10C illustrate an example of an electric appliance according to one embodiment of the present invention.

FIG. 11 illustrates an example of a structure of a plasma CVD apparatus.

FIGS. 12A to 12C show the measurement results of electric characteristics of transistors.

FIGS. 13A to 13C show images of transistors observed with the use of STEM.

FIGS. 14A to 14D illustrate an example of a structure of a transistor.

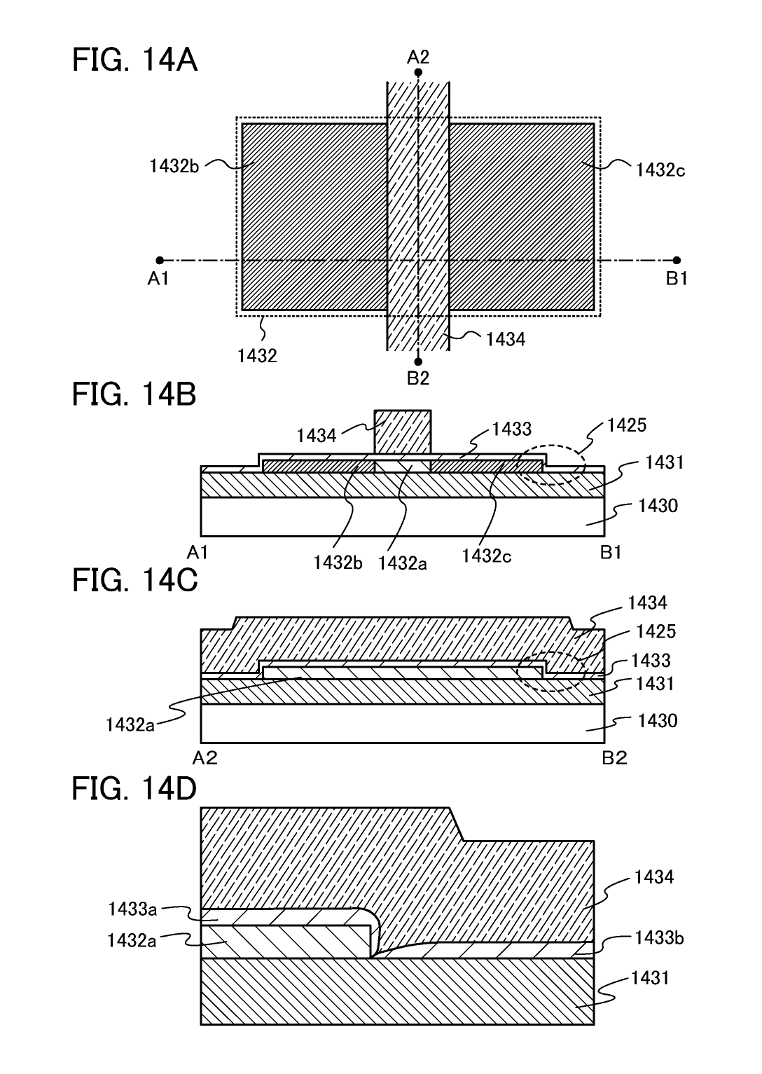

### DETAILED DESCRIPTION OF THE INVENTION

Hereinafter, embodiments of the present invention will be described with reference to the drawings. Note that the invention is not limited to the following description, and it will be easily understood by those skilled in the art that various changes and modifications can be made without departing from the spirit and scope of the invention. Thus, the present invention should not be interpreted as being limited to the following description of the embodiments. In description with reference to the drawings, in some cases, the same reference numerals are used in common for the same portions in different drawings. Further, in some cases, the same hatching patterns are applied to similar parts, and the similar parts are not necessarily designated by reference numerals.

Note that the position, the size, the range, or the like of each structure illustrated in drawings and the like is not accurately represented in some cases for easy understanding. Therefore, the disclosed invention is not necessarily limited to the position, size, range, or the like as disclosed in the drawings and the like.

Note, in this specification, a tapered portion (slanted portion) refers to an end portion of a layer having a tapered shape. The side surface of the tapered portion is inclined to a face that is horizontal to the substrate surface. Note that a taper angle refers to an angle between the face that is horizontal to the substrate surface and the side surface of the tapered portion.

### Embodiment 1

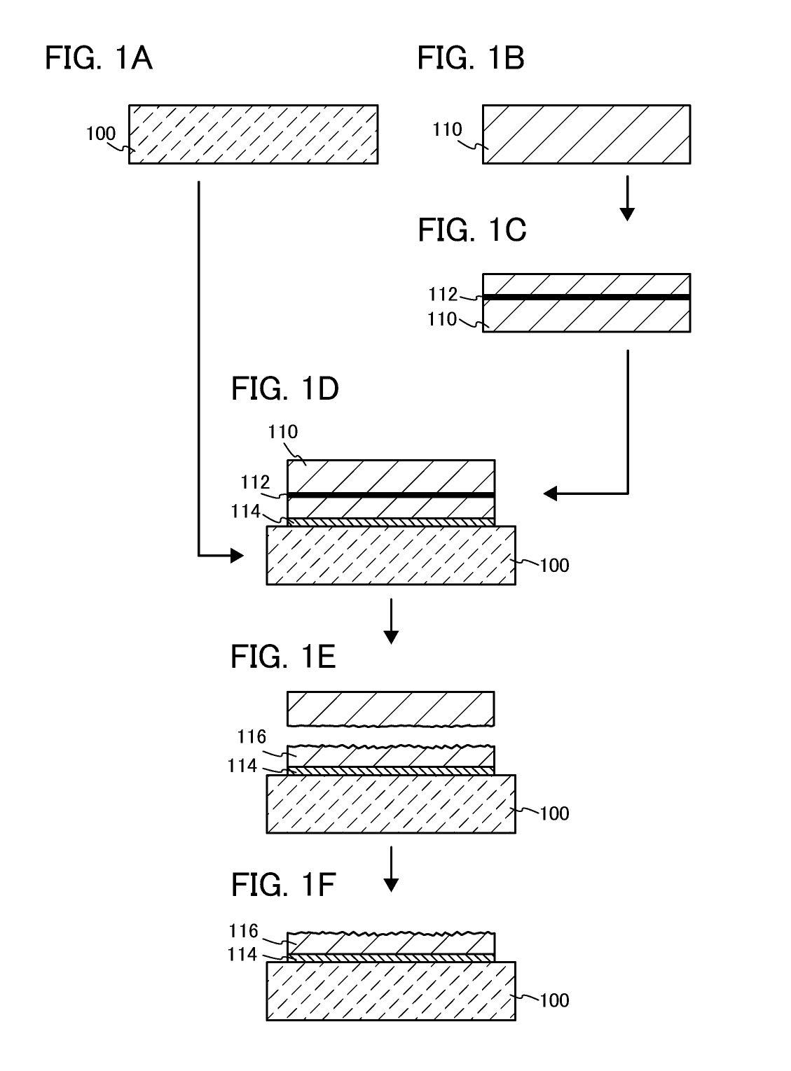

In this embodiment, an example of a method for manufacturing an SOI substrate will be described with reference to FIGS. 1A to 1F, FIGS. 2A to 2C and FIGS. 3A to 3D. Specifically, the case of manufacturing an SOI substrate in which a single crystal semiconductor layer is provided over a base substrate will be described.

First, a base substrate 100 and a single crystal semiconductor substrate 110 are prepared (see FIGS. 1A and 1B).

As the base substrate 100, a substrate formed from an insulator can be used.

As the base substrate 100, specifically, a variety of glass substrates used for electronic industries (e.g. aluminosilicate glass, aluminoborosilicate glass, or barium borosilicate glass), a quartz substrate, a ceramic substrate, or a sapphire substrate can be given as an example.

Alternatively, as the base substrate 100, a semiconductor substrate such as a single crystal silicon substrate or a single crystal germanium substrate may be used. In the case where a semiconductor substrate is used as the base substrate 100, an SOI substrate with high quality can be easily obtained because the temperature condition for heat treatment is eased as compared to the case where a glass substrate or the like is used. As the semiconductor substrate, a solar grade silicon (SOG-Si) substrate, a polycrystalline semiconductor substrate, or the like may be used. In the case of using a SOG-Si substrate, a polycrystalline semiconductor substrate, or the like, manufacturing cost can be reduced as compared to the case of using a single crystal silicon substrate or the like.

In this embodiment, the case of using a glass substrate as the base substrate 100 will be described. Since a glass substrate can have a larger area and is inexpensive, when a glass substrate is used as the base substrate 100, cost reduction can be achieved.

A surface of the base substrate 100 is preferably cleaned in advance. Specifically, the base substrate 100 is subjected to ultrasonic cleaning with a hydrochloric acid/hydrogen peroxide mixture (HPM), a sulfuric acid/hydrogen peroxide mixture (SPM), an ammonium hydroxide/hydrogen peroxide mixture (APM), diluted hydrofluoric acid (DHF), or the like. Through such cleaning treatment, for example, the surface planarity of the base substrate 100 can be improved and abrasive particles left on the surface of the base substrate 100 can be removed.

As the single crystal semiconductor substrate 110, for example, a single crystal semiconductor substrate including a Group 14 element of the periodic table, such as a single crystal silicon substrate, a single crystal germanium substrate, or a single crystal silicon germanium substrate, can be used. Alternatively, a compound semiconductor substrate using gallium arsenide, indium phosphide, or the like can be used. Note that the shape of the substrate to be used as the single crystal semiconductor substrate 110 is not limited to the circular shape typified by a commercially available silicon substrate, for example, and a silicon substrate which is processed into a rectangular shape or the like can also be used. Further, the single crystal semiconductor substrate 110 can be manufactured by a Czochralski (CZ) method or a floating zone (FZ) method.

Note that, in view of removal of contaminants, it is preferable that a surface of the single crystal semiconductor substrate 110 be cleaned with a sulfuric acid/hydrogen peroxide mixture (SPM), an ammonium hydroxide/hydrogen peroxide mixture (APM), a hydrochloric acid/hydrogen peroxide mixture (HPM), diluted hydrofluoric acid (DHF), or the like. Dilute hydrofluoric acid and ozone water may be discharged alternately for cleaning.

Next, the single crystal semiconductor substrate 110 is irradiated with ions accelerated by an electrical field, whereby an embrittled region 112, where the crystal structure is damaged, is formed in the single crystal semiconductor substrate 110 at a predetermined depth from its surface (see FIG. 1C).

The embrittled region 112 formed in the single crystal semiconductor substrate 110 at a predetermined depth from the surface can be formed by irradiating the single crystal semiconductor substrate 110 with ions of hydrogen or the like having kinetic energy caused by acceleration.

The depth of a region where the embrittled region 112 is formed can be adjusted by kinetic energy, mass, charge, incident angle of the ions, or the like. The embrittled region 112 is formed at approximately the same depth as the average penetration depth of the ions. Therefore, the thickness of a single crystal semiconductor layer to be separated from the single crystal semiconductor substrate 110 can be adjusted with the depth at which the ions are added. For example, the average penetration depth may be controlled so that the thickness of the single crystal semiconductor layer is greater than or equal to 10 nm and less than or equal to 500 nm, preferably, greater than or equal to 50 nm and less than or equal to 200 nm.

The ion irradiation can be performed using an ion doping apparatus or an ion implantation apparatus. As a typical example of the ion doping apparatus, there is a non-mass-separation type apparatus in which plasma excitation of a process gas is performed and an object to be processed is irradiated with all kinds of ion species generated. In the ion doping apparatus which is a non-mass-separation type, the object to be processed is irradiated with ion species of plasma without mass separation. In contrast, an ion implantation apparatus is a mass-separation apparatus. In the ion-implantation apparatus, mass separation of ion species of plasma is performed and the object to be processed is irradiated with ion species having predetermined masses.

In this embodiment, an example in which an ion doping apparatus is used to add hydrogen to the single crystal semiconductor substrate 110 will be described. A gas containing hydrogen is used as a source gas. As for the ions used for the irradiation, the proportion of H₃⁺ is preferably set high. Specifically, it is preferable that the proportion of H₃⁺ is greater than or equal to 50% (preferably greater than or equal to 80%) with respect to the total amount of H⁺, H₂⁺, and H₃⁺. Higher proportion of H₃⁺ enables the efficiency of ion irradiation to improve.

Note that the ions used for the irradiation are not limited to ions of hydrogen. Irradiation with ions of helium or the like may be performed. Further, the ions used for the irradiation are not limited to one kind of ions, and irradiation with plural kinds of ions may be performed. For example, in the case of performing irradiation with ions of hydrogen and ions of helium concurrently using an ion doping apparatus, the number of steps can be reduced as compared to the case of performing irradiation of ions of hydrogen and ions of helium in separate steps, and increase in surface roughness of the single crystal semiconductor layer can be suppressed.

Next, the surface of the base substrate 100 and the surface the single crystal semiconductor substrate 110 are disposed to face each other, and the base substrate 100 and the single crystal semiconductor substrate 110 are bonded to each other with an insulating film 114 interposed therebetween (see FIG. 1D).

Bonding is performed as follows: the base substrate 100 and the single crystal semiconductor substrate 110 are disposed in close contact with each other with the insulating film 114 interposed therebetween, and then a pressure of from 1 N/cm² to 500 N/cm² is applied to a portion of the base substrate 100 or the single crystal semiconductor substrate 110. When the pressure is applied, bonding between the base substrate 100 and the insulating film 114 starts from the portion to which the pressure is applied, which forms a bonding spontaneously over the entire surface. This bonding step is performed under the action of the Van der Waals force or hydrogen bonding and can be performed at room temperature.

The insulating film 114 can be formed with a single layer or a stacked layer of insulating films such as a silicon oxide film, a silicon oxynitride film, a silicon nitride film, or a silicon nitride oxide film. These films can be formed using a thermal oxidation method, a CVD (Chemical Vapor Deposition) method, a sputtering method, or the like, on the base substrate 100 or the single crystal semiconductor substrate 110.

Note that in this specification and the like, oxynitride refers to a substance that contains more oxygen (atoms) than nitrogen (atoms). For example, silicon oxynitride is a substance including oxygen, nitrogen, silicon, and hydrogen in ranges of 50 at. % to 70 at. %, 0.5 at. % to 15 at. %, 25 at. % to 35 at. %, and 0.1 at. % to 10 at. %, respectively. Further, nitride oxide refers to a substance that contains more nitrogen (atoms) than oxygen (atoms). For example, silicon nitride oxide is a substance including oxygen, nitrogen, silicon, and hydrogen in ranges of 5 at. % to 30 at. %, 20 at. % to 55 at. %, 25 at. % to 35 at. %, and 10 at. % to 30 at. %, respectively. Note that rates of oxygen, nitrogen, silicon, and hydrogen fall within the aforementioned ranges in the cases where measurement is performed using Rutherford backscattering spectrometry (RBS) or hydrogen forward scattering (HFS). Moreover, the total for the content ratio of the constituent elements does not exceed 100 at. %.

Note that surface treatment is preferably performed on a bonding surface before the base substrate 100 and the single crystal semiconductor substrate 110 are bonded to each other. Surface treatment can improve the bonding strength at the bonding interface between the single crystal semiconductor substrate 110 and the base substrate 100.

As examples of the surface treatment, a wet treatment, a dry treatment, and a combination of both are given. Different wet treatments or different dry treatments may be combined to be performed.

As examples of the wet treatment, ozone treatment using ozone water (ozone water cleaning), megasonic cleaning, two-fluid cleaning (method in which functional water such as pure water or hydrogenated water and a carrier gas such as nitrogen are sprayed together), and the like can be given. As examples of the dry treatment, an ultraviolet treatment, an ozone treatment, a plasma treatment, a plasma treatment with bias application, a radical treatment, and the like can be given. The surface treatment as described above has the effect of improving hydrophilicity and cleanliness of a surface of the object to be processed (i.e., the single crystal semiconductor substrate, the insulating film formed on the single crystal semiconductor substrate, the base substrate, or the insulating film formed on the base substrate). As the result, the bonding strength between the substrates can be improved.

The wet treatment is effective for removal of macro dust and the like attached to the surface of the object to be processed. The dry treatment is effective for removal or decomposition of micro dust such as an organic substance attached to the surface of the object to be processed. The case in which the dry treatment such as ultraviolet treatment is performed and then the wet treatment such as cleaning is performed is preferable because the surface of the object to be processed can be made clean and hydrophilic and generation of watermarks on the surface of the object to be processed can be suppressed.

As the dry treatment, it is preferable to perform surface treatment using ozone or oxygen in an active state, such as singlet oxygen. Ozone or oxygen in an active state such as singlet oxygen enables organic substances attached to the surface of the object to be processed to be removed or decomposed effectively. Further, the treatment using ozone or oxygen in an active state such as singlet oxygen may be combined with treatment using ultraviolet light having wavelengths less than 200 nm, so that the organic substances attached to the surface of the object to be processed can be removed more effectively.

Note that heat treatment for increasing the bonding strength may be performed after the base substrate 100 and the insulating film 114 are bonded to each other. This heat treatment is performed at a temperature at which separation at the embrittled region 112 does not occur (for example, from room temperature to less than 400° C.). Alternatively, the base substrate 100 and the insulating film 114 may be bonded to each other while being heated at a temperature in this temperature range. For this heat treatment, a heating furnace such as a diffusion furnace or a resistance heating furnace, a rapid thermal annealing (RTA) apparatus, a microwave heating apparatus, or the like can be used.

Next, the single crystal semiconductor substrate 110 is separated at the embrittled region 112, whereby the single crystal semiconductor layer 116 is formed over the base substrate 100 with the insulating film 114 interposed therebetween (see FIGS. 1E and 1F). For example, the single crystal semiconductor substrate 110 is separated at the embrittled region 112 by the heat treatment.

By the heat treatment, an element added is separated out as a molecular in microvoids formed in the embrittled region 112, and the internal pressure of the microvoids is increased by thermal motion of the molecular. By the increased pressure, a crack is generated in the embrittled region 112, and accordingly, the single crystal semiconductor substrate 110 is separated along the embrittled region 112. Because the insulating film 114 is bonded to the base substrate 100, the single crystal semiconductor layer 116 which is separated from the single crystal semiconductor substrate 110 and the insulating film 114 remain over the base substrate 100.

Note that it is desirable that the heat treatment temperature in the separation of the single crystal semiconductor substrate 110 be as low as possible. This is because the lower the temperature in the separation is, the more surface roughness of the single crystal semiconductor layer 116 can be decreased. Specifically, the heat treatment temperature in the separation of the single crystal semiconductor substrate 110 is preferably higher than or equal to 400° C. and lower than or equal to 600° C., preferably higher than or equal to 400° C. and lower than or equal to 500° C.

The heat treatment in the separation of the single crystal semiconductor layer 116 can be performed using a heating furnace such as a diffusion furnace or a resistance heating furnace, an RTA apparatus, a microwave heating apparatus, or the like.

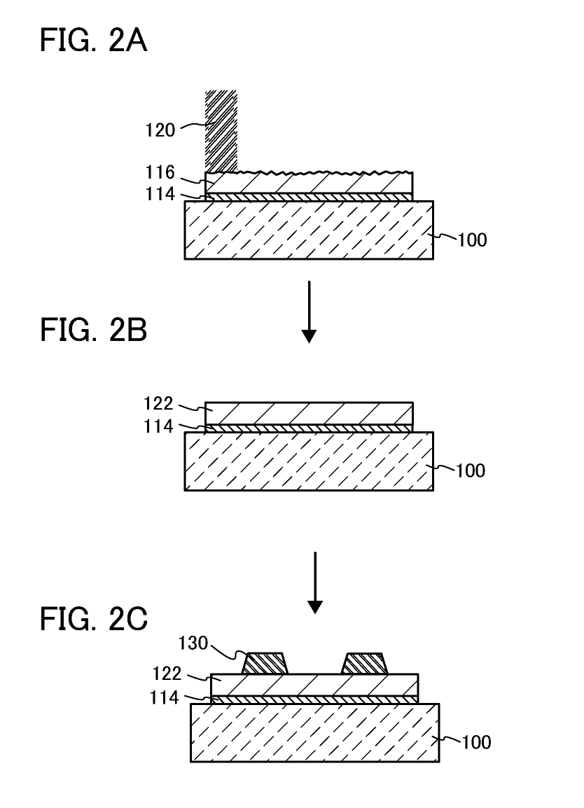

Next, a surface of the single crystal semiconductor layer 116 is irradiated with a laser light 120 to form a single crystal semiconductor layer 122 with improved surface planarity and a reduced number of defects (see FIGS. 2A and 2B).

Note that it is preferable that the single crystal semiconductor layer 116 be subjected to partial melting by the irradiation with the laser light 120. This is because, if the single crystal semiconductor layer 116 is completely melted, the single crystal semiconductor layer 116 is microcrystallized due to disordered nucleation in the single crystal semiconductor layer 116 in a liquid phase, so that crystallinity is lowered. On the other hand, if the single crystal semiconductor layer 116 is partially melted, crystal growth proceeds from a non-melted solid phase portion. Therefore, crystal quality can be improved as compared to the case where the single crystal semiconductor layer 116 is completely melted. In addition, by partial melting, incorporation of oxygen, nitrogen, or the like from the insulating film 114 can be suppressed.

Note that, in the above, by partial melting, the single crystal semiconductor layer 116 is melted to a depth smaller than the depth at an interface between the single crystal semiconductor layer 116 and the insulating film 114 (i.e., smaller than the thickness of the single crystal semiconductor layer 116) by the irradiation with the laser light 120. In other words, the phrase “partially melted state” refers to a state in which the upper portion of the single crystal semiconductor layer 116 is melted into a liquid phase whereas the lower portion is not melted and remains in a solid phase. Further, by completely melting, the single crystal semiconductor layer 116 is melted to the interface between the single crystal semiconductor layer 116 and the insulating film 114. In other words, the phrase “completely melted state” refers to a state in which the single crystal semiconductor layer 116 comes to be in a liquid phase state.

A pulsed laser is preferably used for the irradiation with the laser light. When a pulsed laser is used, high energy can be obtained and thus a partially melted state can easily be produced. The oscillation frequency is preferably, but not limited to, from 1 Hz to 10 MHz.

As examples of the pulsed laser, the following can be given: an Ar laser, a Kr laser, an excimer laser (ArF laser, KrF laser, XeCl laser, and the like), a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a copper vapor laser, a gold vapor laser, and the like.

A continuous wave laser may alternatively be used as long as it enables partial melting. As examples of the continuous wave laser, an Ar laser, a Kr laser, a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a helium-cadmium laser, and the like can be given.

As a wavelength of the laser light 120, a wavelength which is absorbed by the single crystal semiconductor layer 116 is preferably selected, and the wavelength can be determined in consideration of the skin depth of the laser light, and the like. For example, the wavelength is in the range of greater than or equal to 250 nm and less than or equal to 700 nm. In addition, the energy density of the laser light 120 can be determined in consideration of the wavelength of the laser light 120, the skin depth of the laser light 120, the thickness of the single crystal semiconductor layer 116, or the like. For example, as the pulsed laser, when an XeCl excimer laser (wavelength: 308 nm) is used, the energy density of the laser light 120 is in the range of greater than or equal to 300 mJ/cm² and less than or equal to 800 mJ/cm².

The irradiation with the laser light 120 can be performed in an atmosphere containing oxygen such as an air atmosphere or an inert atmosphere such as a nitrogen atmosphere or an argon atmosphere.

In order to perform the irradiation with the laser light 120 in an inert atmosphere, the irradiation with the laser light 120 may be performed in an airtight chamber while the atmosphere in the chamber may be controlled. In the case where the chamber is not used, an inert atmosphere can be formed by spraying an inert gas such as a nitrogen gas to the surface which is to be irradiated with the laser light 120. Note that, as for the atmosphere for irradiation with the laser light 120, the inert atmosphere is more effective in improving the planarity of the single crystal semiconductor layer 122 than the air atmosphere. In addition, in the inert atmosphere, generation of cracks and ridges can be suppressed more effectively than in the air atmosphere, and the applicable energy density range for the laser light 120 is widened.

Note that the irradiation with the laser light 120 may be performed in a reduced-pressure atmosphere. When the irradiation with the laser light 120 is performed in a reduced-pressure atmosphere, the same effects as those obtained by the irradiation in an inert atmosphere can be obtained.

Further, in the above, although the irradiation with the laser light 120 is performed immediately after the heat treatment for separation of the single crystal semiconductor layer 116, this embodiment is not limited to this. Etching treatment may be performed after the heat treatment for separation of the single crystal semiconductor layer 116, to remove a region with many defects on the surface of the single crystal semiconductor layer 116, and then the irradiation with the laser light 120 may be performed. Alternatively, after the surface planarity of the single crystal semiconductor layer 116 is improved by etching treatment or the like, the irradiation with the laser light 120 may be performed. Note that the etching treatment may be either wet etching or dry etching.

Furthermore, before or after the irradiation with the laser light 120 is performed, etching treatment may be performed so that the single crystal semiconductor layer 122 has a desired thickness. As the etching treatment, one of dry etching and wet etching, or etching in which dry etching and wet etching are combined can be employed. Note that, the surface planarity of the single crystal semiconductor layer 122 may also be improved by the etching treatment.

Further, as the above, after the etching treatment is performed so that the single crystal semiconductor layer 122 has a desired thickness, the heat treatment may be performed. The temperature of the heat treatment is, higher than or equal to 300° C. and lower than or equal to 600° C., preferably higher than or equal to 400° C. and lower than or equal to 500° C. The heat treatment can be performed using a heating furnace such as a diffusion furnace or a resistance heating furnace, an RTA apparatus, a microwave heating apparatus, or the like.

Further, before or after the irradiation with the laser light 120 is performed, in order to control the threshold voltage of the transistor, an impurity element may be added to at least a region which functions as a channel formation region of a transistor, in the single crystal semiconductor layer. Examples of an impurity element imparting n-type conductivity include phosphorus, arsenic, or the like; and examples of an impurity element imparting p-type conductivity include boron, aluminum, gallium, or the like. Note that, after the addition of the impurity element, the heat treatment may be performed. By the heat treatment, the impurity element can be activated or defects which may be generated during addition of the impurity element can be reduced.

Next, through a photolithography step, a mask pattern 130 having a tapered portion (slanted portion) over a desired region of the single crystal semiconductor layer 122 is formed (see FIG. 2C).

First, a resist is formed over the single crystal semiconductor layer 122 and the resist is exposed to light, whereby a resist pattern is formed over a desired region of the single crystal semiconductor layer 122. Next, by heating the resist pattern, the resist pattern is reduced in size and the mask pattern 130 having a tapered end portion can be formed.

As the resist, a resist having a novolac resin as its main component, a resist having a polyethylene-based resin as its main component, or the like can be used. These resists are preferable because they have high resistance against dry etching.

As a light-exposure apparatus with which the resist is exposed to light, a stepper, a light-exposure apparatus of a mirror projection exposure method, or the like can be used. Instead of exposing a resist to light by using a light-exposure apparatus, a laser beam direct drawing apparatus may be used to expose a resist to light.

Note that, in a photolithography step, after a resist is formed over the entire surface of the single crystal semiconductor layer 122, the resist may be exposed to light. Alternatively, after a resist is printed in a region where the resist pattern is formed by a printing method, the resist may be exposed to light. By using the printing method, the resist can be saved and cost reduction can be achieved.

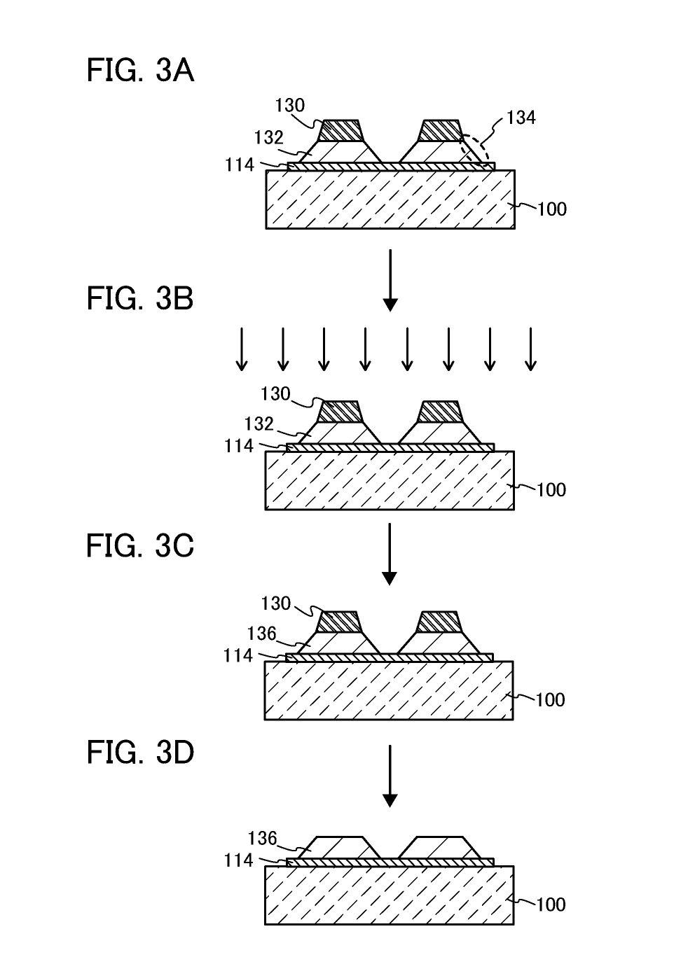

Next, with the use of the mask pattern 130, the single crystal semiconductor layer 122 is etched and an element is isolated, whereby an island-shaped single crystal semiconductor layer 132 having a tapered end portion is formed (see FIG. 3A).

As the etching, dry etching is performed. Dry etching is preferable than wet etching because etching rate can be easily controlled in dry etching; thus, a tapered shape can be formed with high accuracy. Further, dry etching is preferable than wet etching because an undercut is unlikely to be formed in a lower layer in dry etching; thus, anisotropic etching is easily performed.

As the etching gas, a gas containing chlorine (for example, a chlorine-based gas such as chlorine (Cl₂), boron chloride (BCl₃), silicon chloride (SiCl₄), or carbon tetrachloride (CCl₄)) can be used. Alternatively, a gas containing fluorine (for example, a fluorine-based gas such as carbon tetrafluoride (CF₄), sulfur hexafluoride (SF₆), nitrogen trifluoride (NF₃), or trifluoromethane (CHF₃)); hydrogen bromide (HBr); any of these gases to which oxygen (O₂) is added; any of the gases to which a rare gas such as helium (He) or argon (Ar) is added; or the like can be used.

As the dry etching method, a parallel plate RIE (reactive ion etching) method or an ICP (inductively coupled plasma) etching method can be used. By adjusting etching conditions (e.g., the amount of electric power applied to a coiled electrode, the amount of electric power applied to an electrode on the substrate side, and the electrode temperature on the substrate side) as appropriate, the single crystal semiconductor layer 132 is formed into a desired shape.

For example, etching is performed under the following conditions: the flow rates of boron chloride (BCl₃), carbon tetrafluoride (CF₄) and oxygen (O₂) as an etching gas are 10 sccm to 50 sccm, 10 sccm to 50 sccm, and 5 sccm to 15 sccm, respectively; the amount of electric power applied to a coiled electrode is 300 W to 600 W; the electric power applied to the lower electrode (on the bias side) is 50 W to 200 W; and the reaction pressure is 1.5 Pa to 3.0 Pa.

Here, the dry etching of the single crystal semiconductor layer 132 is performed so that the end portion of the single crystal semiconductor layer 132 has a tapered shape. The taper angle is greater than or equal to 30° and less than 90°, preferably, greater than or equal to 30° and less than or equal to 50°. Note that in the following description, the end portion of the single crystal semiconductor layer having a tapered shape is also referred to as a tapered portion.

Note that, a gas containing chlorine, a gas containing fluorine, or the like has a high etching rate with respect to silicon included in the single crystal semiconductor layer. Therefore, by increasing the ratio of the above gases to the etching gas, the taper angle can be increased. In that manner, the ratio of the gases is set as appropriate in accordance with a desired taper angle.

The end portion of the single crystal semiconductor layer 132 has a tapered shape, whereby disconnection of a film formed over the single crystal semiconductor layer (an insulating film, a conductive film, a wiring, or the like) in a later step can be prevented. Further, the tapered end portion of the single crystal semiconductor layer 132 alleviates the concentration of an electric field, so that generation of malfunction of a transistor can be prevented.

Furthermore, after the single crystal semiconductor layer 132 is formed using the mask pattern 130, with the use of the mask pattern 130, etching treatment is performed by an ICP etching method in which a substrate bias is not applied to the end portion of the single crystal semiconductor layer 132. By the etching process, the vicinity of the surface 134 of the tapered portion of the single crystal semiconductor layer 132 (a surface layer of the tapered portion) is removed, whereby a single crystal semiconductor layer 136 is formed (see FIGS. 3B and 3C).

When the island-shaped single crystal semiconductor layer 132 is formed by dry etching, plasma damage or contamination is caused by the dry etching in the vicinity of the surface 134 of the tapered portion which is not covered with the mask pattern 130. Note that, contamination caused by the dry etching includes contamination caused by heavy metal or the like from an etching apparatus or contamination caused by an etching gas by applying the electric power to the upper electrode and the lower electrode of the etching apparatus.

In the single crystal semiconductor layer 132 having a tapered portion, charge is generated at an interface between the single crystal semiconductor layer 132 and an insulating film which is to be formed over the single crystal semiconductor layer in a later step and the interface state is increased, so that poor characteristics of a transistor using the single crystal semiconductor layer are caused. For example, in the case where the transistor is an n-channel transistor, the vicinity of the surface of the tapered portion is negatively charged, and in the case where the transistor is a p-channel transistor, the vicinity of the surface is positively charged.

Further, when the thickness of the single crystal semiconductor layer 132 is increased in order to suppress an increase in the interface state, the step in the end portion of the single crystal semiconductor layer 132 is increased. Therefore, the coverage with a film (an insulating film, a conductive film, a wiring, or the like) which is to be formed over the single crystal semiconductor layer in a later step gets worse and a material of the film remains in a portion where the film is not necessary to be formed, which causes a short-circuit.

On the other hand, in this embodiment, after the island-shaped single crystal semiconductor layer 132 is formed by dry etching, etching in which a substrate bias is not applied is performed, whereby the vicinity of the surface 134 of the tapered portion of the single crystal semiconductor layer 132 which causes an increase in the interface state, is removed and the single crystal semiconductor layer 136 is formed. Therefore, a transistor using the single crystal semiconductor layer 136 whose vicinity of the surface 134 is removed can have favorable characteristics.

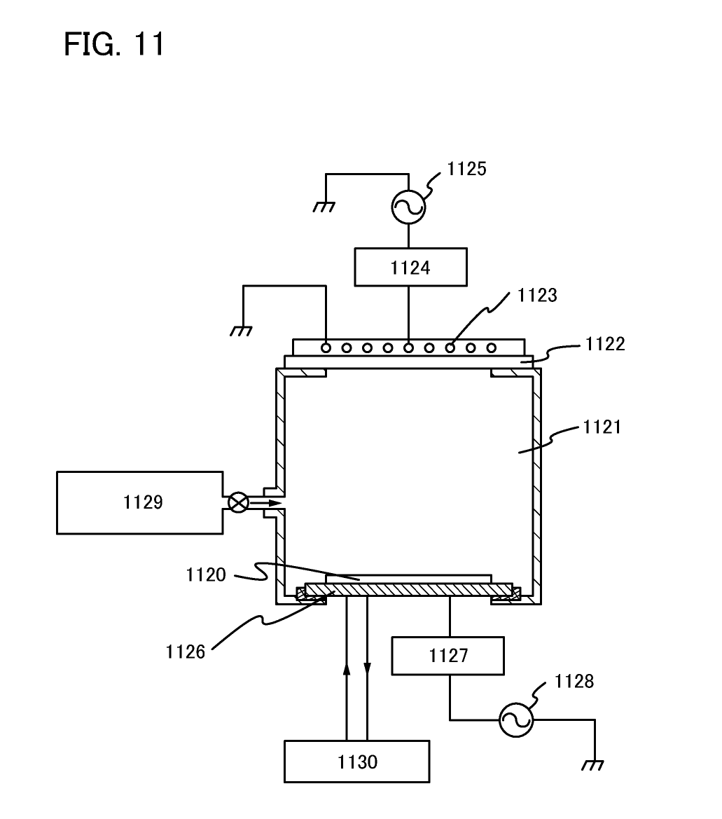

As an example of an apparatus used for dry etching, FIG. 11 illustrates an example of a structure of an ICP etching apparatus.

In the ICP etching apparatus illustrated in FIG. 11, an antenna coil 1123 is provided over a quartz plate 1122 in an upper portion of a chamber 1121, and is connected to a high-frequency power supply 1125 via a matching box 1124. Further, a lower electrode 1126 (on the bias side) which is placed to face the quartz plate 1122 and is provided on an object to be processed 1120 side is connected to a high-frequency power supply 1128 via a matching box 1127.

Furthermore, the lower electrode 1126 is connected to a cooling control device 1130. Note that, the cooling control device 1130 cools oil for cooling. The oil for cooling is circulated between the lower electrode 1126 and the cooling control device 1130, whereby the object to be processed 1120 provided over the lower electrode 1126 can be cooled. In addition, as the oil for cooling, silicone oil, perfluorohexane, perfluoropolyether, or the like, with which fluidity can be maintained when cooling is performed, can be used.

Various gases are supplied from a gas supply portion 1129 to the chamber 1121. As the gas supplied, a gas containing chlorine, a gas containing fluorine, hydrogen bromide (HBr), any of these gases to which oxygen (O₂) is added, any of the gases to which a rare gas such as helium (He) or argon (Ar) is added, or the like can be given.

Here, since the lower electrode 1126 is grounded, the electric power applied to the lower electrode 1126 (on the bias side) can be 0 W. Therefore, the potential on the base substrate side is a ground potential.

The electric power applied to the lower electrode 1126 (on the bias side) is set to 0 W, whereby an ICP etching in which a substrate bias is not applied can be performed.

In the case where the electric power applied to the lower electrode 1126 is set to 0 W, the etching rate of the single crystal semiconductor layer 132 can be slowed down as compared to the case where the electric power is applied. Therefore, removal of the vicinity of the surface 134 of the single crystal semiconductor layer 132 can be performed with high accuracy.

Further, when a substrate bias is applied in etching of the vicinity of the surface 134 of the single crystal semiconductor layer 132, there is concern that plasma damage is caused in the single crystal semiconductor layer by the etching, while the vicinity of the surface 134 is removed. However, in this embodiment, since the vicinity of the surface 134 of the single crystal semiconductor layer 132 is etched with no substrate bias applied, without plasma damage due to the etching, the vicinity of the surface 134 of the single crystal semiconductor layer 132 can be removed.

Furthermore, when a substrate bias is applied in etching the single crystal semiconductor layer 132, there is concern that impurities on the surface of the single crystal semiconductor layer 132 enter in the single crystal semiconductor layer 132. However, in this embodiment, since the vicinity of the surface 134 of the single crystal semiconductor layer 132 is etched with no substrate bias applied, entry of the impurities due to the etching can be prevented.

Moreover, when a substrate bias is applied in etching the single crystal semiconductor layer 132, there is concern that contamination is caused by the dry etching. However, in this embodiment, since the vicinity of the surface 134 of the single crystal semiconductor layer 132 is etched with no substrate bias applied, contamination of the single crystal semiconductor layer 132 caused by the etching can be prevented.

Note that, the vicinity of the surface 134 of the tapered portion, which is to be removed, just occupies the extreme small part with respect to the whole of the single crystal semiconductor layer 132. Therefore, the shape of an inclined surface expressed by the taper angle or the like hardly changes before and after the removal of the vicinity of the surface 134 of the tapered portion.

Accordingly, the end portion of the single crystal semiconductor layer 136 has a tapered shape, the taper angle is greater than or equal to 30° and less than 90°, preferably, greater than or equal to 30° and less than or equal to 50°.

Further, the size of the vicinity of the surface 134 of the single crystal semiconductor layer 132 or the depth from the surface (the range of plasma damage or contamination caused by the dry etching) changes depending on the etching conditions for forming the single crystal semiconductor layer 132. Therefore, the etching conditions other than a substrate bias are set as appropriate in accordance with the state of the vicinity of the surface 134.

As the etching gas, a gas containing chlorine (for example, a chlorine-based gas such as chlorine, boron chloride, silicon chloride, or carbon tetrachloride); carbon tetrafluorid; a gas containing fluorine (for example, a fluorine-based gas such as sulfur hexafluoride or nitrogen trifluoride); any of these gases to which oxygen is added can be used.

For example, etching is performed under the following conditions: the flow rate of chlorine (Cl₂) as an etching gas is 50 sccm to 100 sccm; the amount of electric power applied to a coiled electrode is 100 W to 500 W; the electric power applied to the lower electrode (on the bias side) is 0 W; and the reaction pressure is 1.5 Pa to 3.0 Pa.

Further, in this embodiment, the mask pattern 130 which is used for forming the single crystal semiconductor layer 132 is continuously used in the etching treatment of the vicinity of the surface 134 of the tapered portion. The step of forming the single crystal semiconductor layer 132 and the step of etching the vicinity of the surface 134 can be performed in the same chamber by not performing the step in which the mask pattern 130 is removed between the steps. Further, by leaving the mask pattern 130, a natural oxide film can be prevented from being formed at a surface of the single crystal semiconductor layer 132 covered with the mask pattern 130.

Further, in this embodiment, the mask pattern 130 which is used for forming the single crystal semiconductor layer 132 is continuously used in the etching treatment of the vicinity of the surface 134 of the tapered portion. Therefore, even when the vicinity of the surface 134 is removed in a chamber which is different from the chamber where the single crystal semiconductor layer 132 is formed, a surface of the single crystal semiconductor layer 132 covered with the mask pattern 130 can be prevented from being contaminated, at the time of the transfer to another chamber.

Further, in this embodiment, the vicinity of the surface 134 of the tapered portion is etched with the mask pattern 130 left without being removed.

The etching treatment is performed in the state where the mask pattern 130 is provided over the single crystal semiconductor layer 132, whereby in the etching treatment of the vicinity of the surface 134 of the tapered portion, a surface of the single crystal semiconductor layer 132 covered with the mask pattern 130 can be protected.

Note that, in the case where it is not necessary to concern contamination as described above, the mask pattern 130 may be removed before the etching treatment of the vicinity of the surface 134 of the tapered portion.

Further, in this embodiment, a dry etching method is used for removal of the vicinity of the surface 134 of the tapered portion; however, in the case where the etching rate can be controlled, a wet etching method may be used.

As described above, after the single crystal semiconductor layer 132 is formed by dry etching, the etching treatment in which the potential on the base substrate side is a ground potential is performed to the tapered portion of the single crystal semiconductor layer 132, whereby the vicinity of the surface 134 of the single crystal semiconductor layer 132 is removed and a single crystal semiconductor layer 136 with high quality can be formed.

Next, the mask pattern 130 provided over the single crystal semiconductor layer 136 is removed (see FIG. 3D).

In such a manner, an SOI substrate including the single crystal semiconductor layer in which a portion where plasma damage or contamination is caused by the dry etching is removed can be obtained.

Note that the structure described in this embodiment can be used in appropriate combination with any of structures described in the other embodiments.

### Embodiment 2

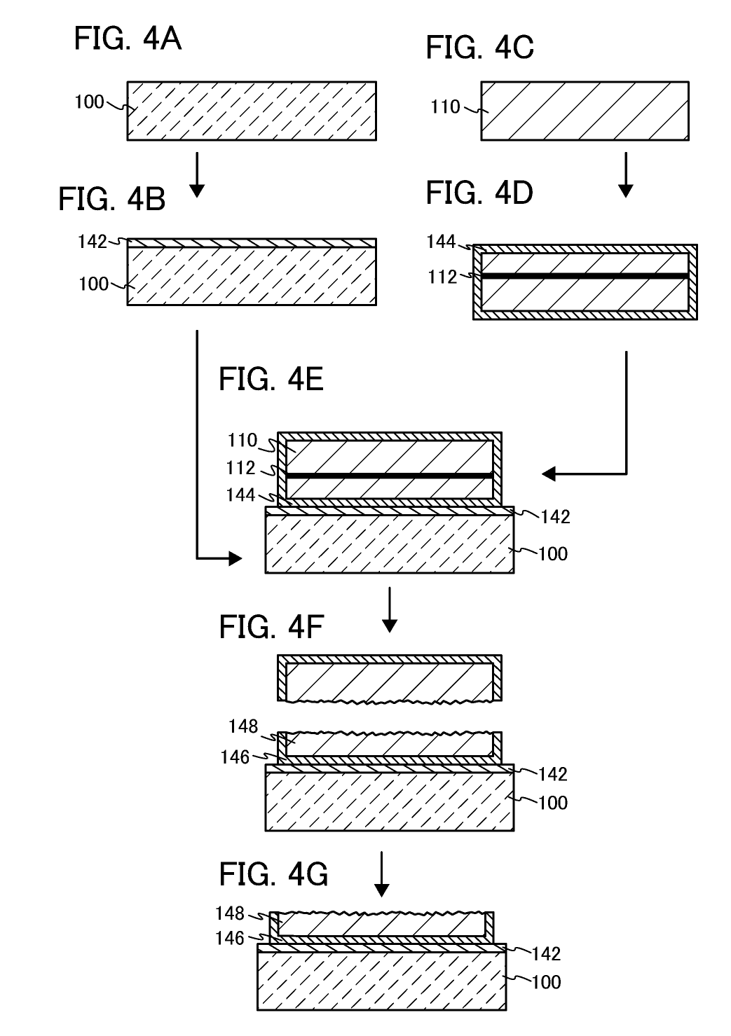

In this embodiment, another example of a method for manufacturing an SOI substrate will be described with reference to FIGS. 4A to 4G, FIGS. 5A to 5C, and FIGS. 6A to 6D.

First, the base substrate 100 and the single crystal semiconductor substrate 110 are prepared (see FIGS. 4A and 4C). For details of the base substrate 100 and the single crystal semiconductor substrate 110, Embodiment 1 can be referred to.

Next, a nitrogen-containing layer 142 is formed on the surface of the base substrate 100 (see FIG. 4B).

As the nitrogen-containing layer 142, for example, a layer including an insulating film containing nitrogen, such as a silicon nitride (SiNₓ) film or a silicon nitride oxide (SiNₓO_{y} (x>y)) film can be used.

The nitrogen-containing layer 142 formed in this embodiment functions as a layer (a bonding layer) to which the single crystal semiconductor layer is bonded in a later step. The nitrogen-containing layer 142 also functions as a barrier layer for preventing impurities contained in the base substrate, such as sodium (Na), from diffusing into the single crystal semiconductor layer.

As described above, the nitrogen-containing layer 142 is used as a bonding layer in this embodiment; thus, the nitrogen-containing layer 142 is preferably formed such that its surface has a predetermined degree of flatness. Specifically, the nitrogen-containing layer 142 is formed such that it has an average surface roughness (Rₐ) of 0.5 nm or less and a root-mean-square surface roughness (Rₘₛ) of 0.60 nm or less, preferably an average surface roughness of 0.35 nm or less and a root-mean-square surface roughness of 0.45 nm or less. The thickness of the nitrogen-containing layer 142 is set to 10 nm or more and 200 nm or less, preferably 50 nm or more and 100 nm or less. With such a high degree of surface planarity, defective bonding of the nitrogen-containing layer 142 and the single crystal semiconductor layer can be prevented.

Next, an oxide film 144 is formed on a surface of the single crystal semiconductor substrate 110 (see FIG. 4D).

The oxide film 144 can be formed with a single layer or a stacked layer of, for example, a silicon oxide film, a silicon oxynitride film, or the like. Examples of a formation method of the oxide film 144 include a thermal oxidation method, a CVD method, or a sputtering method. When the oxide film 144 is formed by a CVD method, a silicon oxide film is preferably formed using organosilane such as tetraethoxysilane (abbreviation: TEOS) (chemical formula: Si(OC₂H₅)₄).

In this embodiment, by subjecting the single crystal semiconductor substrate 110 to thermal oxidation treatment, a silicon oxide film is formed as the oxide film 144. The thermal oxidation treatment is preferably performed in an oxidizing atmosphere to which a halogen is added.

For example, thermal oxidation treatment of the single crystal semiconductor substrate 110 is performed in an oxidizing atmosphere to which hydrogen chloride is added, whereby the oxide film 144 can be formed through chlorine oxidation performed on its surface. In this case, the oxide film 144 contains chlorine atoms.

Chlorine atoms contained in the oxide film 144 cause distortion in the oxide film 144. As a result, the diffusion rate of water in the oxide film 144 is increased. In other words, when water is attached to the surface of the oxide film 144, the water can be quickly absorbed into the oxide film 144 and diffused therein. Thus, defective bonding due to moisture can be suppressed.

Further, chlorine atoms are contained in the oxide film 144, whereby a heavy metal (such as iron (Fe), chromium (Cr), nickel (Ni), or molybdenum (Mo)) which is an extrinsic impurity is captured and thus the single crystal semiconductor substrate 110 can be prevented from being contaminated. Moreover, after the bonding to the base substrate 100, impurities from the base substrate 100, such as sodium (Na), can be fixed, so that contamination of the single crystal semiconductor substrate 110 can be prevented.

Note that the halogen atoms contained in the oxide film 144 are not limited to chlorine atoms. A fluorine atom may be contained in the oxide film 144. As a method of fluorine oxidation of the surface of the single crystal semiconductor substrate 110, a method in which the single crystal semiconductor substrate 110 is soaked in a hydrogen fluoride (HF) solution and then subjected to thermal oxidation treatment in an oxidizing atmosphere, a method in which thermal oxidation treatment is performed in an oxidizing atmosphere to which nitrogen trifluoride (NF₃) is added, or the like can be given.

Note that, in view of removal of contaminants, before forming the oxide film 144, it is preferable that a surface of the single crystal semiconductor substrate 110 be cleaned with a sulfuric acid/hydrogen peroxide mixture (SPM), an ammonium hydroxide/hydrogen peroxide mixture (APM), a hydrochloric acid/hydrogen peroxide mixture (HPM), diluted hydrofluoric acid (DHF), or the like. Dilute hydrofluoric acid and ozone water may be discharged alternately for cleaning.

Next, the single crystal semiconductor substrate 110 is irradiated with ions accelerated by an electrical field, whereby the embrittled region 112, where the crystal structure is damaged, is formed in the single crystal semiconductor substrate 110 at a predetermined depth from the surface (see FIG. 4D). Embodiment 1 can be referred to for the details of formation of the embrittled region 112.

Note that there is a possibility that a heavy metal is added to the single crystal semiconductor substrate 110 when the embrittled region 112 is formed using the ion doping apparatus; however, the ion irradiation is performed through the oxide film 144 containing halogen atoms, so that contamination of the single crystal semiconductor substrate 110 due to the heavy metal can be prevented.

Next, the surface of the nitrogen-containing layer 142 and the surface of the oxide film 144 are disposed to face each other, and the base substrate 100 and the single crystal semiconductor substrate 110 are bonded to each other with the nitrogen-containing layer 142 and the oxide film 144 interposed therebetween (see FIG. 4E).

Bonding is performed as follows: the base substrate 100 and the single crystal semiconductor substrate 110 are disposed in close contact with each other with the nitrogen-containing layer 142 and the oxide film 144 interposed therebetween, and then a pressure of from 1 N/cm² to 500 N/cm² is applied to a portion of the base substrate 100 or the single crystal semiconductor substrate 110. When the pressure is applied, bonding between the nitrogen-containing layer 142 and the oxide film 144 starts from the portion to which the pressure is applied, which forms a bonding spontaneously over the entire surface. This bonding step is performed under the action of the Van der Waals force or hydrogen bonding and can be performed at room temperature.

Note that surface treatment is preferably performed on a bonding surface before the base substrate 100 and the single crystal semiconductor substrate 110 are bonded to each other. Embodiment 1 can be referred to for the details of the surface treatment.

Note that heat treatment for increasing the bonding strength may be performed after the nitrogen-containing layer 142 and the oxide film 144 are bonded to each other. This heat treatment is performed at a temperature at which separation at the embrittled region 112 does not occur (for example, from room temperature to less than 400° C.). Alternatively, the nitrogen-containing layer 142 and the oxide film 144 may be bonded to each other while being heated at a temperature in this temperature range. For this heat treatment, a heating furnace such as a diffusion furnace or a resistance heating furnace, a rapid thermal annealing (RTA) apparatus, a microwave heating apparatus, or the like can be used.

Next, the single crystal semiconductor substrate 110 is separated at the embrittled region 112, whereby the single crystal semiconductor layer 148 is formed over the base substrate 100 with the nitrogen-containing layer 142 and an oxide film 146 interposed therebetween (see FIGS. 4F and 4G). For example, the single crystal semiconductor substrate 110 is separated at the embrittled region 112 by the heat treatment. For the details of the heat treatment, Embodiment 1 can be referred to.

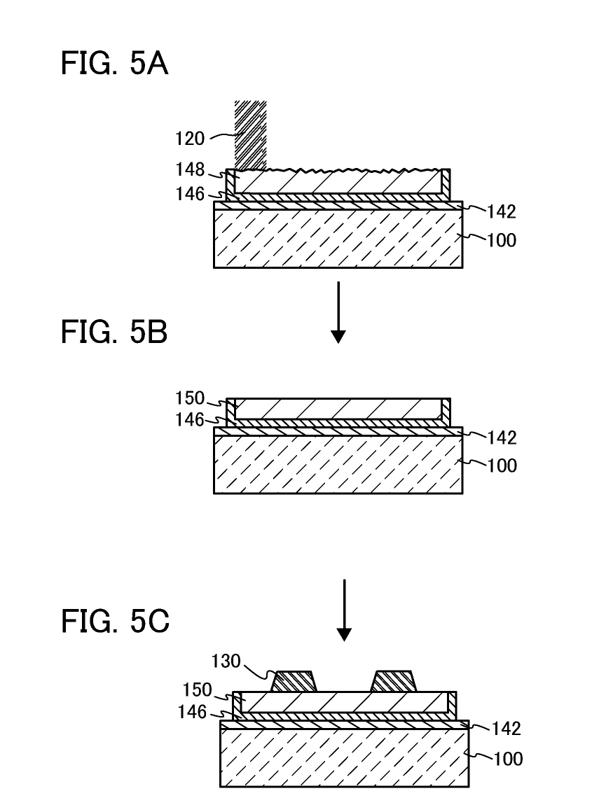

Next, a surface of the single crystal semiconductor layer 148 is irradiated with a laser light 120 to form a single crystal semiconductor layer 150 with improved surface planarity and a reduced number of defects (see FIGS. 5A and 5B). Embodiment 1 can be referred to for the details of the irradiation with the laser light 120.

Further, in the above, although the irradiation with the laser light 120 is performed immediately after the heat treatment for separation of the single crystal semiconductor layer 148, this embodiment is not limited to this. Etching treatment may be performed after the heat treatment for separation of the single crystal semiconductor layer 148, to remove a region with many defects on the surface of the single crystal semiconductor layer 148, and then the irradiation with the laser light 120 may be performed. Alternatively, after the surface planarity of the single crystal semiconductor layer 148 is improved by etching treatment or the like, the irradiation with the laser light 120 may be performed. Note that the etching treatment may be either wet etching or dry etching.

Furthermore, before or after the irradiation with the laser light 120 is performed, etching treatment may be performed so that the single crystal semiconductor layer 150 has a desired thickness. Embodiment 1 can be referred to for the details of the etching treatment.

Further, as the above, after the etching treatment is performed so that the single crystal semiconductor layer 150 has a desired thickness, the heat treatment may be performed. Embodiment 1 can be referred to for the details of the heat treatment.

Further, before or after the irradiation with the laser light 120 is performed, in order to control the threshold voltage of the transistor, an impurity element may be added to at least a region which functions as a channel formation region of a transistor, in the single crystal semiconductor layer. Embodiment 1 can be referred to for the addition of the impurity element.

Next, through a photolithography step, a mask pattern 130 having a tapered portion (slanted portion) over a desired region of the single crystal semiconductor layer 150 is formed (see FIG. 5C). Embodiment 1 can be referred to for the details of formation of the mask pattern 130.

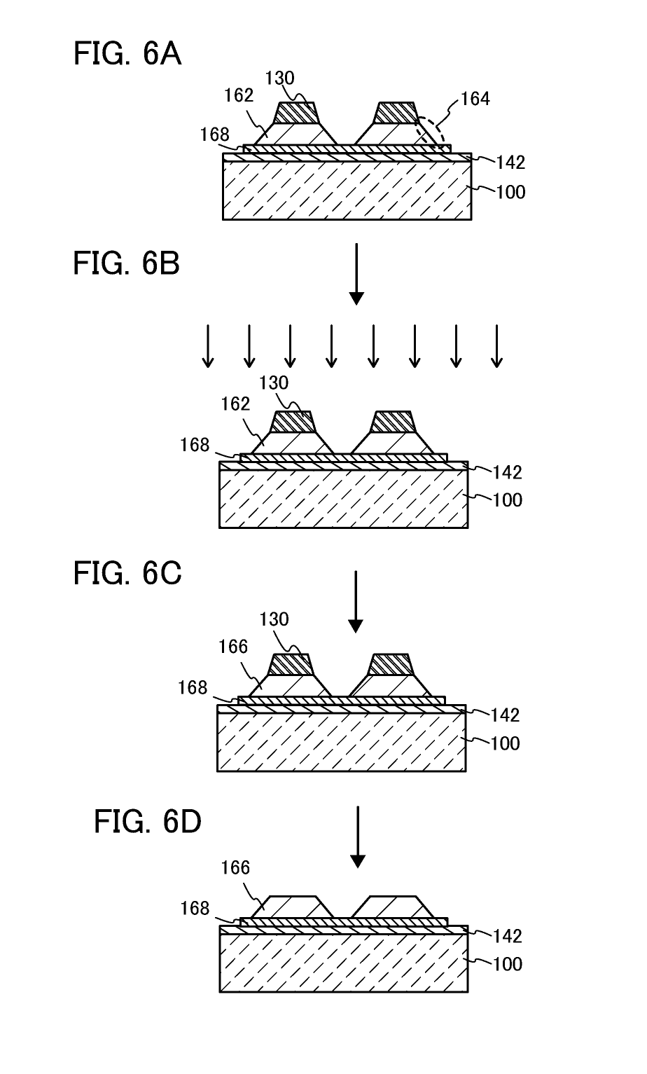

Next, with the use of the mask pattern 130, the single crystal semiconductor layer 150 is etched and an element is isolated, whereby an island-shaped single crystal semiconductor layer 162 having a tapered end portion is formed (see FIG. 6A).

Note that, in FIG. 6A, an oxide film 168 by removing the oxide film 146 partly is formed; however, the oxide film 146 is not limited to the structure in FIG. 6A and is formed into a desired shape as appropriate.

As the etching, dry etching is performed.

As the etching gas, a gas containing chlorine (for example, a chlorine-based gas such as chlorine (Cl₂), boron chloride (BCl₃), silicon chloride (SiCl₄), or carbon tetrachloride (CCl₄)) can be used. Alternatively, a gas containing fluorine (for example, a fluorine-based gas such as carbon tetrafluoride (CF₄), sulfur hexafluoride (SF₆), nitrogen trifluoride (NF₃), or trifluoromethane (CHF₃)); hydrogen bromide (HBr); any of these gases to which oxygen (O₂) is added; any of the gases to which a rare gas such as helium (He) or argon (Ar) is added; or the like can be used.

As the dry etching method, a parallel plate RIE (reactive ion etching) method or an ICP (inductively coupled plasma) etching method can be used. By adjusting etching conditions (e.g., the amount of electric power applied to a coiled electrode, the amount of electric power applied to an electrode on the substrate side, and the electrode temperature on the substrate side) as appropriate, the single crystal semiconductor layer 162 is formed into a desired shape.

For example, etching is performed under the following conditions: the flow rates of boron chloride (BCl₃), carbon tetrafluoride (CF₄) and oxygen (O₂) as an etching gas are 10 sccm to 50 sccm, 10 sccm to 50 sccm, and 5 sccm to 15 sccm, respectively; the amount of electric power applied to a coiled electrode is 300 W to 600 W; the electric power applied to the lower electrode (on the bias side) is 50 W to 200 W; and the reaction pressure is 1.5 Pa to 3.0 Pa.

Here, the dry etching of the single crystal semiconductor layer 150 is performed so that the end portion of the single crystal semiconductor layer 150 has a tapered shape. The taper angle is greater than or equal to 30° and less than 90°, preferably, greater than or equal to 30° and less than or equal to 50°. Note that in the following description, the end portion of the single crystal semiconductor layer having a tapered shape is also referred to as a tapered portion.

The end portion of the single crystal semiconductor layer 162 has a tapered shape, whereby disconnection of a film formed over the single crystal semiconductor layer (an insulating film, a conductive film, a wiring, or the like) in a later step can be prevented. Further, the tapered end portion of the single crystal semiconductor layer 162 alleviates the concentration of an electric field, so that generation of malfunction of a transistor can be prevented.

Furthermore, after the single crystal semiconductor layer 162 is formed using the mask pattern 130, with the use of the mask pattern 130, etching treatment is performed by an ICP etching method in which a substrate bias is not applied to the end portion of the single crystal semiconductor layer 162. By the etching process, the vicinity of the surface 164 of the tapered portion of the single crystal semiconductor layer 162 (a surface layer of the tapered portion) is removed, whereby a single crystal semiconductor layer 166 is formed (see FIGS. 6B and 6C).

When the island-shaped single crystal semiconductor layer 162 is formed by dry etching, plasma damage or contamination is caused by the dry etching in the vicinity of the surface 164 of the tapered portion which is not covered with the mask pattern 130. In the single crystal semiconductor layer 162 having a tapered portion, charge is generated at an interface between the single crystal semiconductor layer 162 and an insulating film which is to be formed over the single crystal semiconductor layer in a later step and the interface state is increased, so that poor characteristics of a transistor using the single crystal semiconductor layer are caused. For example, in the case where the transistor is an n-channel transistor, the vicinity of the surface of the tapered portion is negatively charged, and in the case where the transistor is a p-channel transistor, the vicinity of the surface is positively charged.

Further, when the thickness of the single crystal semiconductor layer 166 is increased in order to suppress an increase in the interface state, the step in the end portion of the single crystal semiconductor layer 166 is increased. Therefore, the coverage with a film (an insulating film, a conductive film, a wiring, or the like) which is to be formed over the single crystal semiconductor layer in a later step gets worse and a material of the film remains in an unnecessary portion when the film is formed, which causes a short-circuit.

On the other hand, in this embodiment, after the island-shaped single crystal semiconductor layer 162 is formed by dry etching, etching is performed in the state where the potential on the base substrate side is a ground potential, whereby the vicinity of the surface 164 of the tapered portion of the single crystal semiconductor layer 162 which causes an increase in the interface state, is removed and the single crystal semiconductor layer 166 is formed. Therefore, a transistor using the single crystal semiconductor layer 166 whose vicinity of the surface 164 is removed can have favorable characteristics.

Further, in this embodiment, the mask pattern 130 which is used for forming the single crystal semiconductor layer 162 is continuously used in the etching treatment of the vicinity of the surface 164 of the tapered portion. The step of forming the single crystal semiconductor layer 162 and the step of etching the vicinity of the surface 164 can be performed in the same chamber by not performing the step in which the mask pattern 130 is removed between the steps. Further, by leaving the mask pattern 130, a natural oxide film can be prevented from being formed at a surface of the single crystal semiconductor layer 162 covered with the mask pattern 130.

Further, in this embodiment, the same mask pattern 130 which is used for forming the single crystal semiconductor layer 162 is used in the etching treatment of the vicinity of the surface 164 of the tapered portion. Therefore, even when the vicinity of the surface 164 is removed in a chamber which is different from the chamber where the single crystal semiconductor layer 162 is formed, a surface of the single crystal semiconductor layer 162 covered with the mask pattern 130 can be prevented from being contaminated, at the time of the transfer to another chamber.

Further, in this embodiment, the vicinity of the surface 164 of the tapered portion is etched with the mask pattern 130 left without being removed.

The etching treatment is performed in the state where the mask pattern 130 is provided over the single crystal semiconductor layer 162, whereby in the etching treatment of the vicinity of the surface 164 of the tapered portion, a surface of the single crystal semiconductor layer 162 covered with the mask pattern 130 can be protected.

Note that, in the case where it is not necessary to concern contamination as described above, the mask pattern 130 may be removed before the etching treatment of the vicinity of the surface 164 of the tapered portion.

Further, in this embodiment, a dry etching method is used for removal of the vicinity of the surface 164 of the tapered portion; however, in the case where the etching rate can be controlled, a wet etching method may be used.

As described above, after the single crystal semiconductor layer 162 is formed by dry etching, the etching treatment is performed by an ICP etching method in which a substrate bias is not applied to the tapered portion of the single crystal semiconductor layer 162, whereby the vicinity of the surface 164 of the single crystal semiconductor layer 162 is removed and a single crystal semiconductor layer 166 with high quality can be formed.

Next, the mask pattern 130 provided over the single crystal semiconductor layer 166 is removed (see FIG. 6D).

In such a manner, an SOI substrate including the single crystal semiconductor layer in which a portion where plasma damage or contamination is caused by the dry etching is removed can be obtained.

Note that the structure described in this embodiment can be used in appropriate combination with any of structures described in the other embodiments.

### Embodiment 3

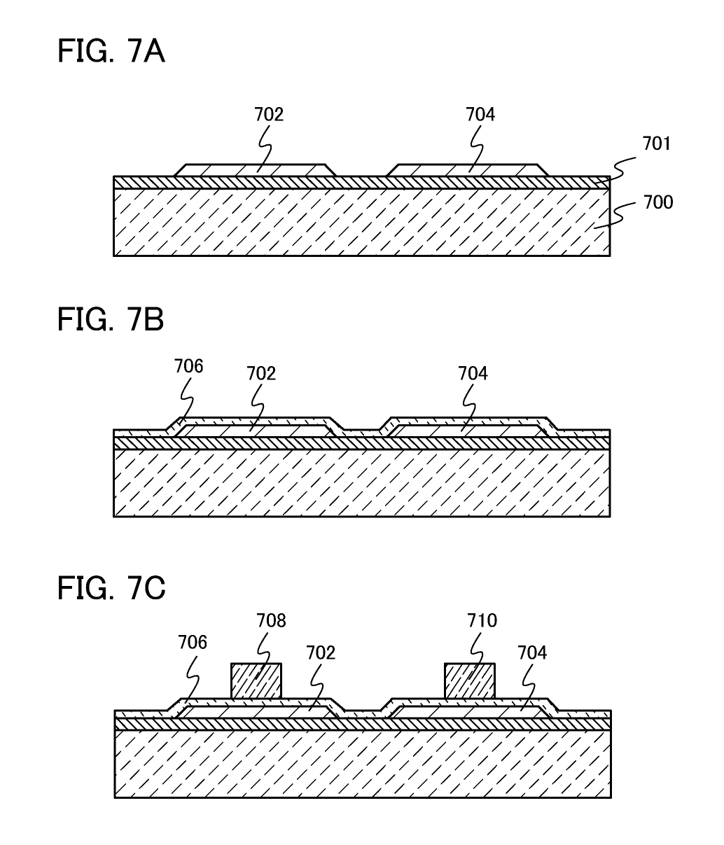

In this embodiment, an example of a method for manufacturing a semiconductor device using the SOI substrate shown in the above embodiments will be described with reference to FIGS. 7A to 7C, FIGS. 8A to 8D, and FIGS. 9A and 9B. Here, as an example of a semiconductor device, an example of a method for manufacturing a semiconductor device including a plurality of transistors using the SOI substrates will be described. Note that, with the use of transistor described in this embodiment, various semiconductor devices can be manufactured.

FIG. 7A is a cross-sectional view of an SOI substrate including a single crystal semiconductor layer manufactured by the method described in Embodiment 1. Note that, although the case where a semiconductor device is manufactured with the use of the SOI substrate described in Embodiment 1 is described in this embodiment, a semiconductor device with the use of the SOI substrate described in Embodiment 2 may be manufactured.

A single crystal semiconductor layer 702 and a single crystal semiconductor layer 704 are formed over a base substrate 700 with an insulating film 701 interposed therebetween.

In order to control the threshold voltage of a transistor, an impurity element imparting p-type conductivity (boron, aluminum, gallium, or the like) or an impurity element imparting n-type conductivity (phosphorus, arsenic, or the like) may be added to each of the single crystal semiconductor layer 702 and the single crystal semiconductor layer 704. A region to which the impurity element is added and the kind of the impurity element to be added can be changed as appropriate. For example, an impurity element imparting p-type conductivity is added to a single crystal semiconductor layer included in an n-channel transistor and an impurity element imparting n-type conductivity is added to a single crystal semiconductor layer included in a p-channel transistor.

Next, a gate insulating film 706 is formed so as to cover the single crystal semiconductor layer 702 and the single crystal semiconductor layer 704 (see FIG. 7B). In this embodiment, as the gate insulating film 706, a silicon oxide film is formed by a plasma CVD method.

Note that, instead of a silicon oxide film, the gate insulating film 706 may be formed to have a single-layer structure or a stacked-layer structure of a silicon oxynitride film, a silicon nitride oxide film, a silicon nitride film, a hafnium oxide film, an aluminum oxide film, a tantalum oxide film, or the like.

Instead of a plasma CVD method, the gate insulating film 706 may be formed by a sputtering method, a method using oxidation or nitridation by a high density plasma treatment. Alternatively, the gate insulating film 706 may be formed by thermally oxidizing the single crystal semiconductor layer 702 and the single crystal semiconductor layer 704. When thermal oxidation is performed, as the base substrate 700, a glass substrate having a certain degree of heat resistance is preferably used.

Next, a conductive film is formed over the gate insulating film 706, and then, the conductive film is processed (patterned) into a predetermined shape, whereby a gate electrode 708 and a gate electrode 710 are formed over the single crystal semiconductor layer 702 and the single crystal semiconductor layer 704, respectively (see FIG. 7C).

The conductive film can be formed by a CVD method, a sputtering method, or the like. As a material of the conductive film, a metal such as tantalum (Ta), tungsten (W), titanium (Ti), molybdenum (Mo), aluminum (Al), copper (Cu), chromium (Cr), or niobium (Nb) can be used. Alternatively, an alloy material containing the above metal as a main component or a compound containing the above metal may be used.

In this embodiment, the gate electrode 708 and the gate electrode 710 are formed using a single-layer conductive film; however, the gate electrode 708 and the gate electrode 710 are not limited to this structure. The gate electrode 708 and the gate electrode 710 may be formed using a plurality of conductive films which are stacked. For example, in the case of a two-layer structure, a stacked structure of a molybdenum film, a titanium film, a titanium nitride film, or the like as a lower layer and an aluminum film or the like as an upper layer is used. In the case of a three-layer structure, a stacked structure of a molybdenum film, an aluminum film, and a molybdenum film, a stacked structure of a titanium film, an aluminum film, and a titanium film, or the like is used.

Note that a mask used for forming the gate electrodes 708 and 710 may be formed using a material such as silicon oxide or silicon nitride oxide. In this case, a step of forming a mask by patterning a silicon oxide film, a silicon nitride oxide film, or the like is additionally needed. However, decrease in film thickness of the mask in etching the conductive film is smaller than that in the case of using a resist material; thus, the gate electrodes 708 and 710 whose shapes are controlled with high accuracy can be formed.

Alternatively, the gate electrodes 708 and 710 may be selectively formed by a droplet discharge method without using a mask. Here, a droplet discharge method refers to a method in which droplets containing a predetermined composition are discharged or ejected to form a predetermined pattern, and includes an ink jet method and the like in its category.

Alternatively, the gate electrodes 708 and 710 can be formed by etching the conductive film to have desired tapered shapes with an inductively coupled plasma (ICP) etching method with appropriate adjustment of etching conditions (e.g., the amount of electric power applied to a coiled electrode, the amount of electric power applied to a substrate-side electrode, the temperature of the substrate-side electrode, and the like). In addition, the above described tapered shape can be controlled by the shape of the mask. Note that, as the etching gas, a gas containing chlorine (for example, a chlorine-based gas such as chlorine, boron chloride, silicon chloride, or carbon tetrachloride); a gas containing fluorine (for example, a fluorine-based gas such as carbon tetrafluoride, sulfur hexafluoride, or nitrogen trifluoride); any of these gases to which oxygen (O₂) is added; or the like can be used.

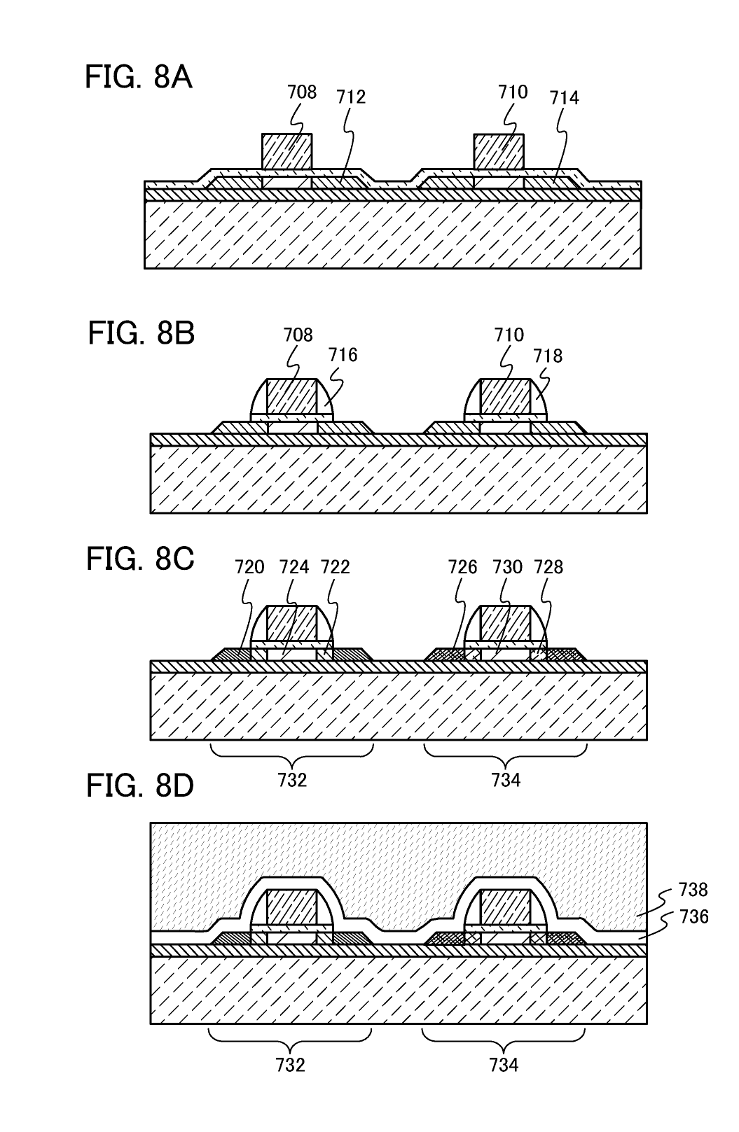

Then, impurity elements each imparting one conductivity type are added into the single crystal semiconductor layer 702 and the single crystal semiconductor layer 704 using the gate electrodes 708 and 710 as masks (see FIG. 8A).

In this embodiment, an impurity element imparting n-type conductivity (for example, phosphorus or arsenic) is added to the single crystal semiconductor layer 702, and an impurity element imparting p-type conductivity (for example, boron) is added to the single crystal semiconductor layer 704.

Note that when the impurity element imparting n-type conductivity is added to the single crystal semiconductor layer 702, the single crystal semiconductor layer 704 to which the impurity element imparting p-type conductivity is added is covered with a mask or the like so that the impurity element imparting n-type conductivity is added to the single crystal semiconductor layer 702 selectively. When the impurity element imparting p-type conductivity is added to the single crystal semiconductor layer 704, the single crystal semiconductor layer 702 to which the impurity element imparting n-type conductivity is added is covered with a mask or the like so that the impurity element imparting p-type conductivity is added to the single crystal semiconductor layer 704 selectively.

Alternatively, after one of an impurity element imparting p-type conductivity and an impurity element imparting n-type conductivity is added to the single crystal semiconductor layers 702 and 704, the other of the impurity element imparting p-type conductivity and the impurity element imparting n-type conductivity may be added only to one of the single crystal semiconductor layers at a higher concentration.

By the addition of the impurity elements, impurity regions 712 and impurity regions 714 are formed in the single crystal semiconductor layer 702 and the single crystal semiconductor layer 704, respectively.

Next, a sidewall 716 is formed on the side surface of the gate electrode 708, and a sidewall 718 is formed on the side surface of the gate electrode 710 (see FIG. 8B).

The sidewalls 716 and 718 can be formed by, for example, forming an insulating film so as to cover the gate insulating film 706 and the gate electrodes 708 and 710 and by partially etching the insulating film by anisotropic etching. Note that the gate insulating film 706 may also be etched partially by the anisotropic etching described above.

The insulating film forming the sidewalls 716 and 718 is formed to have a single-layer structure or a stacked-layer structure of a silicon film, a silicon oxide film, a silicon nitride film, a silicon oxynitride film, a silicon nitride oxide film, a film containing an organic material, or the like. Further, the insulating film forming the sidewalls 716 and 718 is preferably formed by a plasma CVD method a sputtering method, or the like. In this embodiment, as the insulating film forming the sidewalls 716 and 718, a silicon oxide film is formed by a plasma CVD method.

Further, as the etching gas used in etching the insulating film, a mixed gas of trifluoromethane (CHF₃) and helium (He) can be used. Note that the process for forming the sidewalls 716 and 718 is not limited to this.

Next, an impurity element which imparts one conductivity type is added to the single crystal semiconductor layers 702 and 704 by using the gate insulating film 706, the gate electrodes 708 and 710, and the sidewalls 716 and 718 as masks (see FIG. 8C). Note that the impurity elements imparting the same conductivity type as the impurity elements which have been added in the previous step may be added to the single crystal semiconductor layer 702 and the single crystal semiconductor layer 704 at higher concentrations.

Here, when the impurity element imparting n-type conductivity is added to the single crystal semiconductor layer 702, the single crystal semiconductor layer 704 to which the impurity element imparting p-type conductivity is added is covered with a mask or the like so that the impurity element imparting n-type conductivity is added to the single crystal semiconductor layer 702 selectively. When the impurity element imparting p-type conductivity is added to the single crystal semiconductor layer 704, the single crystal semiconductor layer 702 to which the impurity element imparting n-type conductivity is added is covered with a mask or the like so that the impurity element imparting p-type conductivity is added to the single crystal semiconductor layer 704 selectively.

By the addition of the impurity element, a pair of high-concentration impurity regions 720, a pair of low-concentration impurity regions 722, and a channel formation region 724 are formed in the single crystal semiconductor layer 702. In addition, by the addition of the impurity element, a pair of high-concentration impurity regions 726, a pair of low-concentration impurity regions 728, and a channel formation region 730 are formed in the single crystal semiconductor layer 704. The high-concentration impurity regions 720 and the high-concentration impurity regions 726 each serve as a source region or a drain region, and the low-concentration impurity regions 722 and the low-concentration impurity regions 728 each serve as an LDD (lightly doped drain) region.

Note that the sidewalls 716 formed over the single crystal semiconductor layer 702 and the sidewalls 718 formed over the single crystal semiconductor layer 704 may be formed so as to have the same length or different lengths in a direction in which carriers move (in a direction parallel to a so-called channel length).

For example, each of the sidewalls 718 over the single crystal semiconductor layer 704 which constitutes part of a p-channel transistor is preferably formed to have a longer length in the direction in which carriers are transported than that of each of the sidewalls 716 over the single crystal semiconductor layer 702 which constitutes part of an n-channel transistor. By increasing the lengths of the sidewalls 718 of the p-channel transistor, a short channel effect due to diffusion of boron can be suppressed; therefore, boron can be added to the source region and the drain region at high concentration. Accordingly, the resistance of the source region and the drain region can be sufficiently reduced.

Through the process described above, an n-channel transistor 732 and a p-channel transistor 734 are formed. Note that although a conductive film serving as a source electrode or a drain electrode is not formed in the stage shown in FIG. 8C, a structure including the conductive film serving as a source electrode or a drain electrode may be referred to as a transistor.

Next, an insulating film 736 is formed to cover the n-channel transistor 732 and the p-channel transistor 734 (see FIG. 8D).

The formation of the insulating film 736 can prevent impurities such as an alkali metal and an alkaline-earth metal from entering the n-channel transistor 732 and the p-channel transistor 734. Specifically, the insulating film 736 is preferably formed using a material such as silicon oxide, silicon nitride, silicon oxynitride, silicon nitride oxide, aluminum nitride, aluminum oxide, or the like. In this embodiment, as the insulating film 736, a silicon nitride oxide film is used. Note that although the insulating film 736 is formed to have a single-layer structure in this embodiment, the insulating film 736 may have a stacked-layer structure. For example, in the case of a two-layer structure as the insulating film 736, a stacked structure of a silicon oxynitride film and a silicon nitride oxide film can be used. Note that the insulating film 736 is not necessarily provided.

Next, an insulating film 738 is formed over the insulating film 736 to cover the n-channel transistor 732 and the p-channel transistor 734 (see FIG. 8D).

The insulating film 738 may be formed using an organic material having heat resistance, such as a polyimide, an acrylic resin, a benzocyclobutene-based resin, a polyamide, or an epoxy resin. In addition to such organic materials, it is also possible to use a low-dielectric constant material (a low-k material), a siloxane-based resin, silicon oxide, silicon nitride, silicon oxynitride, silicon nitride oxide, PSG (phosphosilicate glass), BPSG (borophosphosilicate glass), alumina, or the like. Here, the siloxane-based resin corresponds to a resin including a Si—O—Si bond which is formed using a siloxane-based material as a starting material. The siloxane-based resin may include fluorine, an alkyl group, or aromatic hydrocarbon, as well as hydrogen, as a substituent. Note that the insulating film 738 may be formed by stacking a plurality of insulating films formed from any of the above materials.

The insulating film 738 can be formed, depending on the material, by a method such as a CVD method, a sputtering method, an SOG method, a spin coating method, a dipping method, a spray coating method, or a droplet discharge method (e.g., an inkjet method, screen printing, or offset printing), or a tool such as a doctor knife, a roll coater, a curtain coater, or a knife coater.

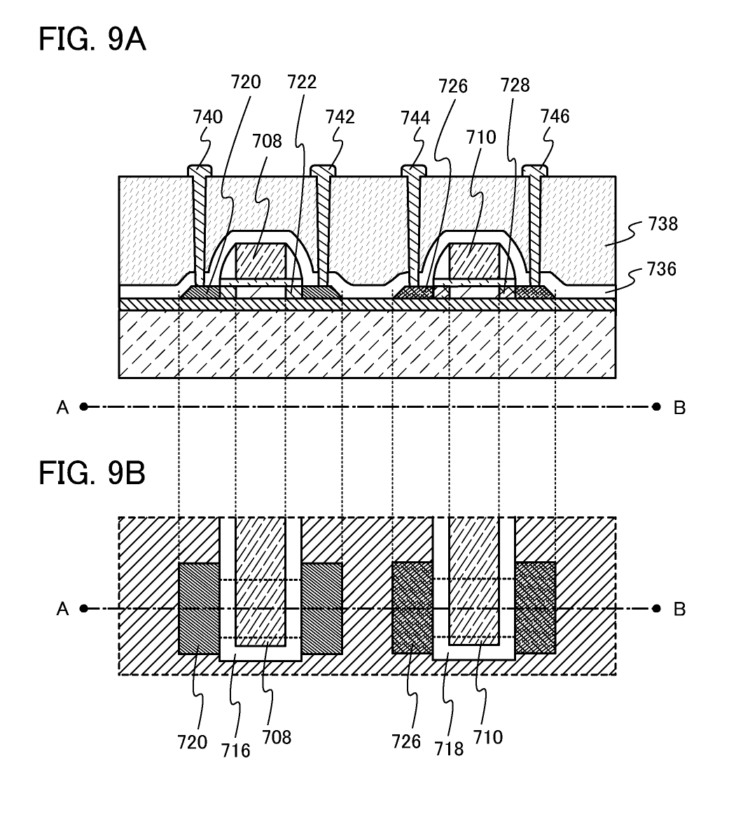

Next, contact holes are formed in the insulating films 736 and 738 so that each of the single crystal semiconductor layers 702 and 704 is partly exposed. Then, conductive films 740 and 742 which are in contact with the single crystal semiconductor layer 702 through the contact holes and conductive films 744 and 746 which are in contact with the single crystal semiconductor layer 704 through the contact holes are formed (see FIG. 9A).

The contact holes can be formed by etching using a mixed gas of trifluoromethane (CHF₃) and helium (He), for example.

The conductive films 740, 742, 744, and 746 function as source and drain electrodes.

The conductive films 740, 742, 744, and 746 can be formed by a CVD method, a sputtering method, or the like. As the material, aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), silicon (Si), or the like can be used. Moreover, an alloy containing the above described material as its main component or a compound containing the above described material may be used. Further, the conductive films 740, 742, 744, and 746 may each have a single-layer structure or a stacked structure.

As an alloy containing aluminum (Al) as its main component, for example, there is an alloy containing aluminum as its main component and also containing nickel, or an alloy containing aluminum as its main component and also containing nickel and one or both of carbon and silicon. Aluminum and aluminum silicon (Al—Si), which have low resistance and are inexpensive, are suitable as a material for forming the conductive films 740, 742, 744, and 746. In particular, aluminum silicon is preferable because a hillock can be prevented from generating due to resist baking at the time of patterning. Further, a material in which copper (Cu) is mixed into aluminum at approximately 0.5% may be used instead of silicon (Si).

In the case where each of the conductive films 740, 742, 744, and 746 is formed to have a stacked structure, a stacked structure of a barrier film, an aluminum silicon film, and a barrier film, a stacked structure of a barrier film, an aluminum silicon film, a titanium nitride film, and a barrier film, or the like is preferably employed, for example.

Note that the barrier film is, a film formed of titanium, titanium nitride, molybdenum, molybdenum nitride, or the like. By forming the conductive films such that an aluminum silicon film is interposed between barrier films, generation of hillocks of aluminum or aluminum silicon can be sufficiently prevented. Moreover, by forming the barrier film using titanium that is a highly reducible element, even if a thin oxide film is formed over the single crystal semiconductor layers 702 and 704, the oxide film is reduced by the titanium contained in the barrier film, whereby favorable contact can be obtained between the single crystal semiconductor layer 702 and the conductive films 740 and 742 and between the single crystal semiconductor layer 704 and the conductive films 744 and 746.

Further, in the conductive films 740, 742, 744, and 746, it is also possible to stack a plurality of barrier films. In that case, for example, each of the conductive films 740, 742, 744, and 746 can be formed to have a five-layer structure including, for example, a titanium film, a titanium nitride film, an aluminum silicon film, a titanium film, and a titanium nitride film in this order from the bottom; or a stacked-layer structure including more than five layers.

Further, as the conductive films 740, 742, 744, and 746, by a CVD method, tungsten silicide which is formed using a tungsten hexafluoride (WF₆) gas and a silane (SiH₄) gas may be used. Alternatively, tungsten obtained by hydrogen reduction of tungsten hexafluoride (WF₆) may be used.

The conductive films 740 and 742 are connected to the high-concentration impurity regions 720 in the n-channel transistor 732. The conductive films 744 and 746 are connected to the high-concentration impurity regions 726 in the p-channel transistor 734.

FIG. 9B is a plan view of the n-channel transistor 732 and the p-channel transistor 734 which are illustrated in FIG. 9A. Here, the cross section taken along the broken line joining A and B in FIG. 9B corresponds to FIG. 9A. Note that the insulating film 736, the insulating film 738, the conductive film 740, the conductive film 742, the conductive film 744, and the conductive film 746 are omitted in FIG. 9B.

Note that although the case where the n-channel transistor 732 and the p-channel transistor 734 each include one electrode serving as a gate electrode (the case where the n-channel transistor 732 and the p-channel transistor 734 include the gate electrodes 708 and 710) is described in this embodiment as an example, this embodiment is not limited to this structure. The transistors may have a multi-gate structure in which a plurality of electrodes serving as gate electrodes are included and electrically connected to one another.

In such a manner, an SOI substrate including the single crystal semiconductor layer in which a portion where plasma damage or contamination is caused by the dry etching is removed is used, whereby a transistor having excellent electric characteristics can be obtained.

Note that the structure described in this embodiment can be used in appropriate combination with any of structures described in the other embodiments.

### Embodiment 4

In this embodiment, an electric appliance using the SOI substrate, the transistor or the semiconductor device, which are described in the above embodiments will be described.

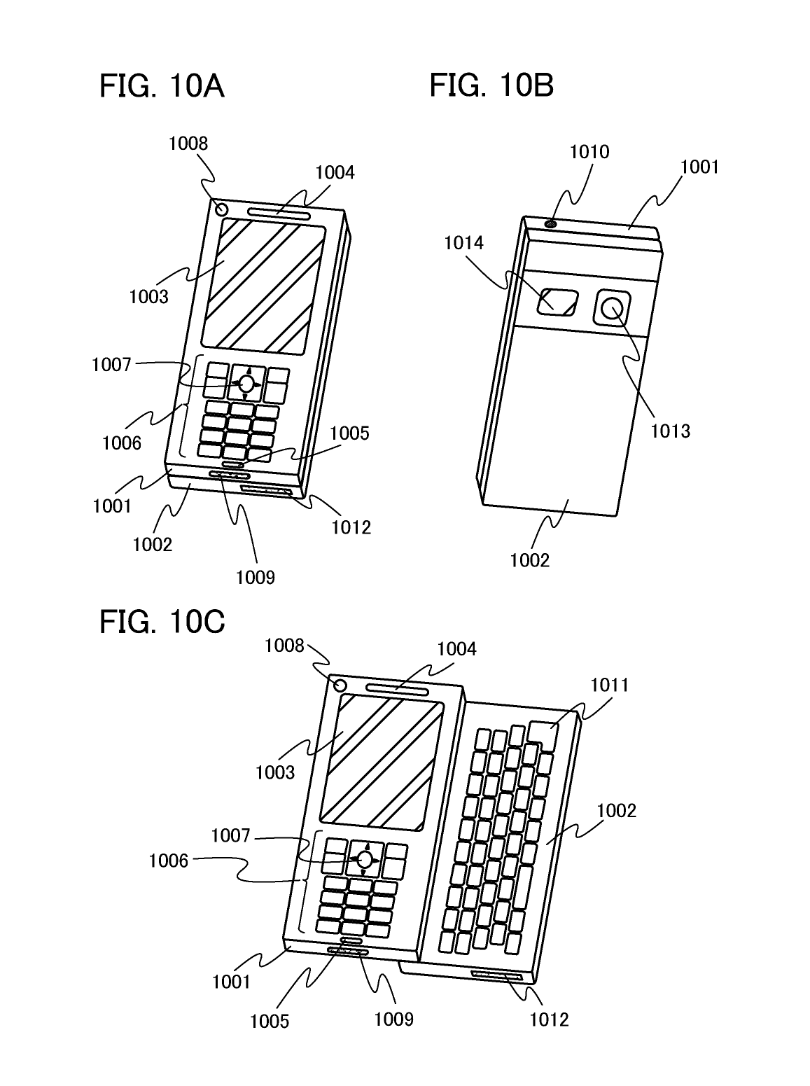

Examples of electric appliances include cameras such as video cameras and digital cameras; navigation systems; sound reproduction devices (such as car audio systems and audio components); computers; game machines; portable information terminals (such as mobile computers, mobile phones, portable game machines, and e-book readers); image reproduction devices each provided with a storage medium (specifically, devices each provided with a display device that reproduces the audio data stored in a storage medium such as a digital versatile disc (DVD) and displays image data stored therein); and the like. As an example of an electric appliance, a structure of a mobile phone will be described with reference to FIGS. 10A to 10C.

FIGS. 10A to 10C illustrate an example of a mobile phone. FIG. 10A is a front view, FIG. 10B is a rear view, and FIG. 10C is a front view in which two housings are slid. The mobile phone has the two housings 1001 and 1002. The mobile phone is a so-called smartphone which has both functions of a mobile phone and a portable information terminal, and incorporates a computer and can process a variety of data processing in addition to voice calls.

The mobile phone has the housings 1001 and 1002. The housing 1001 includes a display portion 1003, a speaker 1004, a microphone 1005, operation keys 1006, a pointing device 1007, a front camera lens 1008, an external connection terminal jack 1009, an earphone terminal 1010, and the like. The housing 1002 includes a keyboard 1011, an external memory slot 1012, a rear camera 1013, a light 1014, and the like. In addition, an antenna is included in the housing 1001.

Further, in addition to the above components, a non-contact IC chip, a small size memory device, or the like may be incorporated in the mobile phone.

The housings 1001 and 1002 which overlap with each other (see FIG. 10A) can be developed by sliding as illustrated in FIG. 10C. Furthermore, since the display portion 1003 and the front camera lens 1008 are provided in the same plane, the mobile phone can be used as a videophone. Further, a still image and a moving image can be taken by the rear camera 1013 and the light 1014 by using the display portion 1003 as a viewfinder.

The display portion 1003 can incorporate a display panel or a display device using the SOI substrate, the transistor or the semiconductor device, which are described in the above embodiments.

With the use of the speaker 1004 and the microphone 1005, the mobile phone can be used as a sound recording device (recorder) or a sound reproducing device. Further, with the use of the operation keys 1006, operation of incoming and outgoing calls, simple information input for electronic mail or the like, scrolling of a screen displayed on the display portion, cursor motion for selecting information displayed on the display portion, and the like are possible.

If much information needs to be treated in documentation, use as a portable information terminal, and the like, it is convenient to use the keyboard 1011. In the case where the mobile phone is used as a portable information terminal, smooth operation with the keyboard 1011 and the pointing device 1007 can be performed. An AC adaptor and various types of cables such as a USB cable can be connected to the jack 1009 for an external connection terminal, and charging and data communication with a personal computer or the like are possible. Further, by inserting a recording medium in the external memory slot 1012, a larger amount of data can be stored and transferred.

The rear face of the housing 1002 is provided with the rear camera 1013 and the light 1014 (see FIG. 10B), and still images and moving images can be taken using the display portion 1003 as a viewfinder.

Furthermore, in addition to the above-described functions and structures, the mobile phone may also have an infrared communication function, a USB port, a television one-segment broadcasting receiving function, a contactless IC chip, an earphone jack, or the like.

In such a manner, the reliability can be increased when the display portion of the electric appliance includes the SOI substrate, the transistor or the semiconductor device, which are described in the above embodiments.

The structure described in this embodiment can be used in appropriate combination with the structures described in other embodiments.

### Example 1

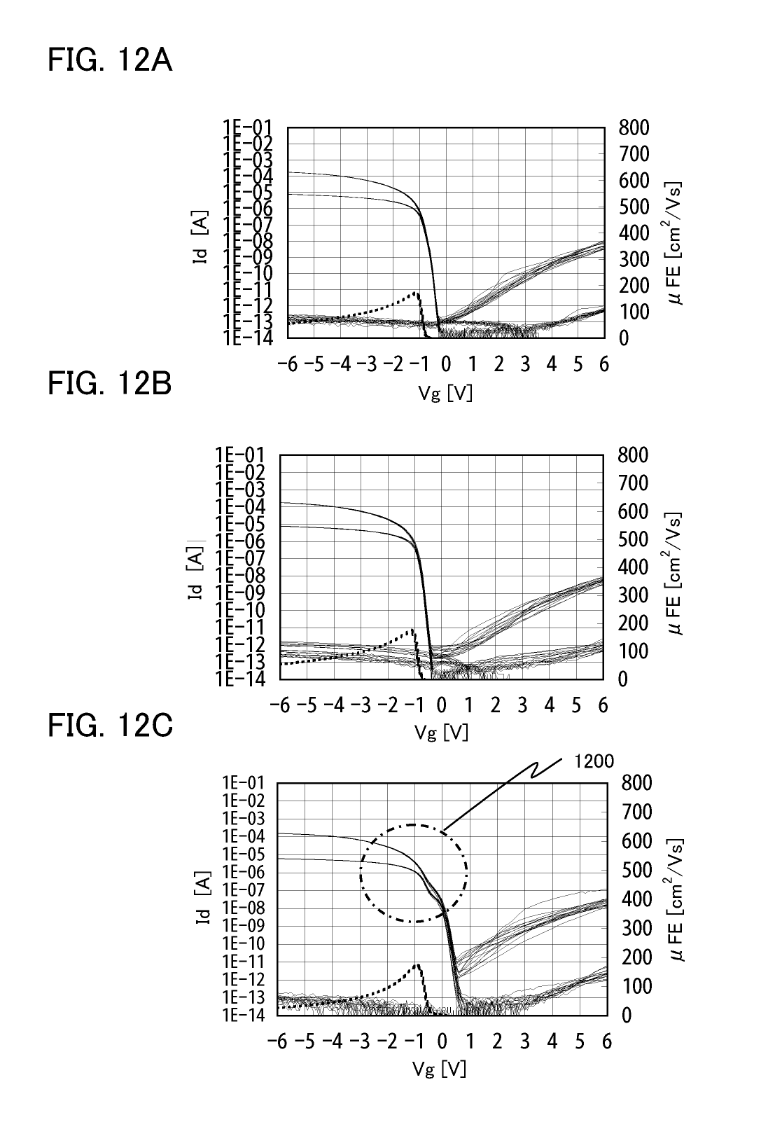

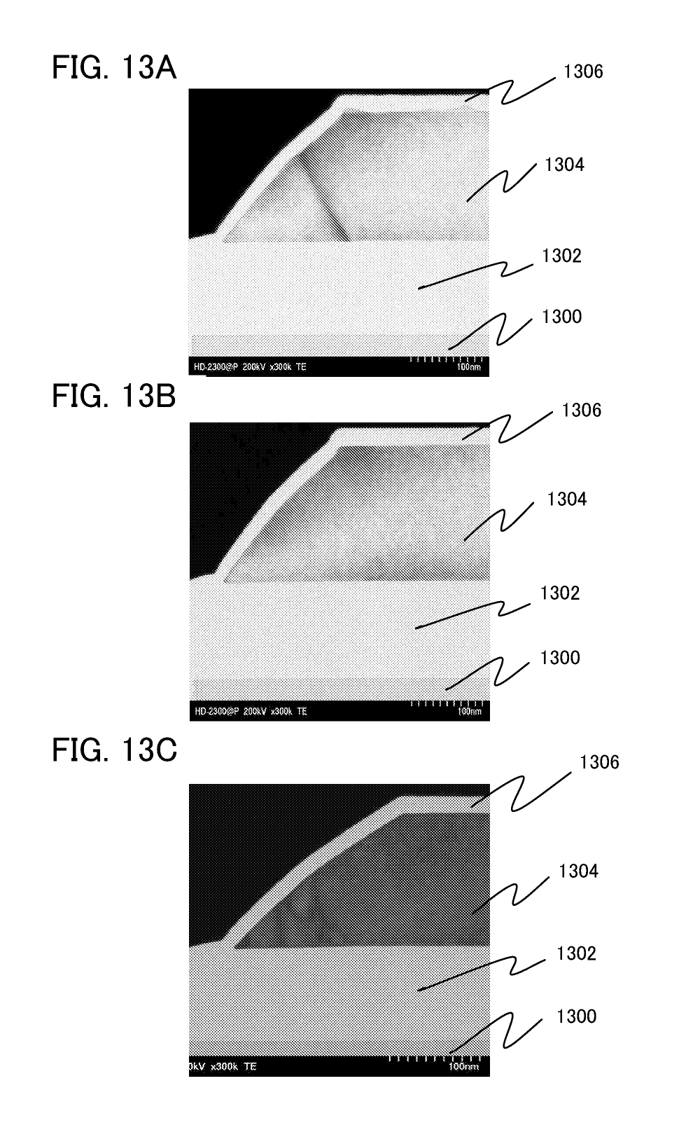

In this example, when the SOI substrate is manufactured by etching treatment with an ICP etching method in which a substrate bias is not applied to the end portion of the single crystal semiconductor layer and a transistor is formed using the SOI substrate, an effect on electric characteristics of the transistor, or the like is described with reference to FIGS. 12A to 12C and FIGS. 13A to 13C. Note that a p-channel transistor was manufactured as a transistor in this example.

### <Manufacturing Process of Transistor>

First, a manufacturing process of a transistor using the SOI substrate according to one embodiment of the present invention will be described.

The SOI substrate used in this example has a structure in which a base substrate and a single crystal semiconductor layer is bonded to each other with an insulating film interposed therebetween. As the base substrate, a glass substrate with a thickness of 0.7 mm was used. As the single crystal semiconductor layer, a single crystal silicon layer with a thickness of 145 nm was used. Further, as the insulating film, a silicon oxide film formed by performing thermal oxidation on the single crystal silicon substrate in an oxidizing atmosphere to which chlorine was added was used. The thickness of the silicon oxide film was 100 nm.

After the bonding, the surface of the single crystal silicon layer was irradiated with a laser light. As a laser emitting a laser light, a XeCl excimer laser (wavelength: 308 nm and repetition rate: 30 Hz) was used. The irradiation with the laser light was performed with a nitrogen gas blown on the samples at room temperature in the following manner. The cross section of the laser light was shaped into a linear form by an optical system. The scanning rate of the laser light was set to 0.5 mm/sec and the number of beam shots was set to about 20.

Further, channel doping was performed to control the threshold voltage. In this example, the impurity element imparting p-type conductivity was added to a region which functions as a channel formation region of the single crystal silicon layer. As the impurity element imparting p-type conductivity, boron was used. Channel doping was performed as follows: the flowing rate of boron trifluoride (BF₃) which was a source gas was 0.3 sccm, the accelerating voltage was set at 30 kV, and boron was added so that the dose was 1.3×10¹²/cm².

Next, a resist pattern was formed over a desired region of the single crystal silicon layer and the resist pattern was heated, whereby a mask pattern having a tapered end portion was formed. The heat treatment was performed at 150° C. for 0.3 hours.

Next, the single crystal silicon layer was etched using the mask pattern, so that an island-shaped single crystal semiconductor layer having a tapered end portion was formed.

As the etching, dry etching was performed, and an ICP etching method was used. As the etching gas, a mixed gas of boron chloride (BCl₃), carbon tetrafluoride (CF₄) and oxygen (O₂) was used; the flow rates were set to 36 sccm, 36 sccm, and 8 sccm, respectively, in this order. Further, the electric power applied to a coiled electrode was 450 W, the electric power applied to a bias side was 100 W, reaction pressure was 2.0 Pa, and the electrode temperature on the substrate side was 70° C.

Then, with the use of the mask pattern, the vicinity of the surface of the end portion of the island-shaped single crystal semiconductor layer was removed by etching. Here, the SOI substrate was manufactured under two etching conditions. What the two etching conditions have in common was that the electric power applied to a bias side was 0 W in ICP etching, or the like.

In the first etching conditions, the vicinity of the surface of the end portion of the island-shaped single crystal semiconductor layer was removed by dry etching. As the etching, an ICP etching method was used. The electric power applied to a coiled electrode was 200 W, the electric power applied to a bias side was 0 W, reaction pressure was 2.0 Pa, and the electrode temperature on the substrate side was 70° C. Further, as the etching gas, chlorine (Cl₂) was used, and the flow rate was set to 100 sccm. Note that, the taper angle of the end portion of the island-shaped single crystal silicon layer was about 30°.

In the second etching conditions, the vicinity of the surface of the end portion of the island-shaped single crystal silicon layer was removed by dry etching. As the etching, an ICP etching method was used. The electric power applied to a coiled electrode was 200 W, the electric power applied to a bias side was 0 W, reaction pressure was 2.0 Pa, and the electrode temperature on the substrate side was 70° C. Further, as the etching gas, carbon tetrafluoride (CF₄) was used, and the flow rate was set to 100 sccm. Note that, the taper angle of the end portion of the island-shaped single crystal silicon layer was about 30°.

Next, the mask pattern was removed, whereby the SOI substrate was manufactured. The transistor using the SOI substrate manufactured by performance of etching treatment under the first etching conditions and the transistor using the SOI substrate manufactured by performance of etching treatment under the second etching conditions are referred to as a first transistor and a second transistor, respectively.

Note that the first transistor and the second transistor are p-channel transistors in which as the impurity element imparting p-type conductivity, boron is added to regions in which a source region and a drain region of the single crystal silicon layer are formed so that the dose of boron is 1.0×10¹⁵/cm².

Further, the first transistor and the second transistor are top-gate transistors in which a channel formation region of the single crystal silicon layer and a gate electrode are overlapped with the gate insulating film interposed therebetween. As the gate insulating film, a silicon oxide film with a thickness of 20 nm was formed, and the gate electrode was formed to have a structure in which a tantalum nitride film with a thickness of 30 nm and a tungsten film with a thickness of 370 nm are stacked.

### <Manufacturing Process of Transistor for Comparison>

A manufacturing process of a transistor using the SOI substrate for comparison will be described.

In the method for manufacturing the SOI substrate for comparison, since steps up to a step of forming the island-shaped single crystal semiconductor layer having a tapered end portion by etching the single crystal silicon layer are same as the steps in the method for manufacturing the SOI substrate according to one embodiment of the present invention, description thereof is omitted.

Next, an SOI substrate was manufactured by removing the mask pattern without removing the vicinity of the surface of the end portion of the island-shaped single crystal silicon layer. The transistor using the SOI substrate is referred to as the transistor for comparison.

Note that the transistor for comparison is a p-channel transistors in which as the impurity element imparting p-type conductivity, boron is added to regions in which a source region and a drain region of the single crystal silicon layer are formed so that the dose of boron is 1.0×10¹⁵/cm².

Further, the transistor for comparison is a top-gate transistor. As the gate insulating film, a silicon oxide film with a thickness of 20 nm was formed, and the gate electrode was formed to have a structure in which a tantalum nitride film with a thickness of 30 nm and a tungsten film with a thickness of 370 nm are stacked.

FIGS. 12A to 12C show the measurement results of electric characteristics of the transistors manufactured through the above steps. FIG. 12A shows electric characteristics of the first transistor, FIG. 12B shows electric characteristics of the second transistor, and FIG. 12C shows electric characteristics of the transistor for comparison.

In FIGS. 12A to 12C, the horizontal axis represents the gate voltage (Vg, the unit is V), the left vertical axis represents the drain current (Id, the unit is A), and the right vertical axis represents the field-effect mobility (μFE, the unit is cm²/Vs). Further, the solid line represents current (Id)-voltage (Vg) characteristic, the broken line represents the field-effect mobility. Note that the field-effect mobility of the thin film transistor in this example was calculated under the following condition: the channel length was 9.9 μm; the channel width was 8.3 μm; and the thickness of the single crystal silicon layer was 20 nm.

As shown in FIG. 12C, in the curve showing Id-Vg characteristics of the transistor for comparison, generation of a kink was confirmed as shown in a range 1200. A reason why a kink was generated in the curve showing current-voltage characteristics of the transistor for comparison was that the vicinity of the surface of the end portion of the island-shaped single crystal silicon layer was removed.

The transistor for comparison can be considered to have a transistor in which an end portion of a single crystal silicon layer having a tapered shape (tapered portion) is a channel formation region (also referred to as an edge transistor) and a transistor in which a central portion of a single crystal semiconductor layer is a channel formation region (also referred to as a main transistor).

Here, the edge transistor includes a tapered portion where plasma damage or contamination is caused by the dry etching when the island-shaped single crystal silicon layer is formed. Further, in the edge transistor, negative charge is accumulated at an interface between the above described single crystal silicon layer having a tapered portion and the gate insulating film in contact with the single crystal silicon layer, whereby the interface state increases.

Therefore, the interface state of the edge transistor is higher than that of the main transistor; thus, the threshold voltage of the edge transistor is lower than that of the main transistor. Further, the transistor for comparison has a structure in which the edge transistor and the main transistor are connected in parallel. Accordingly, the characteristics of the whole transistor for comparison reflect both of the characteristics of the main transistor and the characteristics of the edge transistor, whereby Id-Vg characteristics have a kink as shown in FIG. 12C.

On the other hand, in both of the first transistor and the second transistor using the SOI substrate according to one embodiment of the present invention, as shown in FIGS. 12A and 12B, generation of a kink was confirmed in the curve showing Id-Vg characteristics.

The first transistor and the second transistor are transistors in which the island-shaped single crystal silicon layer is formed by dry etching, and then, the vicinity of the surface of the tapered portion is removed by ICP etching in which the electric power applied to a bias side is 0 W. By removing the vicinity of the surface of the tapered portion, the adverse effect of plasma damage or contamination can be removed and an increase in the interface state can be suppressed; thus, a kink was not generaged.

Further, as electric characteristics of each transistor, the off-state current (Ioff) and the on/off ratio (Ion/Ioff) were measured. Here, “off-state current” is current which flows between a source and a drain when a transistor is in an off state. In the case of a p-channel transistor, the off-state current is a current which flows between a source electrode and a drain electrode when gate voltage is lower than threshold voltage of the transistor. Further, the on/off ratio refers to the ratio of on-state current to off-state current.

In the first transistor subjected to ICP etching in which the electric power applied to a bias side was 0 W, the off-state current was 0.1 pA and the on/off ratio was 6.0×10⁸. In the second transistor, the off-state current was 0.5 pA and the on/off ratio was 1.3×10⁸. On the other hand, in the transistor for comparison, the off-state current was 4.7 pA and the on/off ratio was 0.3×10⁸.

As described above, by application of the present invention, the off-state current can be reduced and the on/off ratio can be increased; thus, it was proved that a transistor with excellent switching characteristics can be manufactured.

Further, FIGS. 13A to 13C show images which are the cross section of the taper portion of the single crystal silicon layer of each transistor observed with the use of an STEM (Scanning Transmission Electron Microscope).

In FIGS. 13A to 13C, a glass substrate 1300, a silicon oxynitride film 1302, a single crystal silicon layer 1304 and a silicon oxide film 1306 are shown as the base substrate, the insulating film, the single crystal semiconductor layer and the gate insulating film, respectively.

The shape of the tapered portion hardly changed before (FIG. 13C) and after (FIGS. 13A and 13B) removing the vicinity of the surface of the tapered portion of the island-shaped single crystal silicon layer by ICP etching in which the electric power applied to a bias side was 0 W. When ICP etching in which the electric power applied to a bias side was 0 W was performed, the shape of the tapered portion was not changed. Therefore, a problem such as a coverage defect with the silicon oxide film 1306 over the single crystal silicon layer 1304 was not generated.

As described above, by application of the present invention, it was confirmed that generation of a kink can be suppressed by removing the vicinity of the surface of the tapered portion of the island-shaped single crystal silicon layer.

This application is based on Japanese Patent Application serial no. 2010-165811 filed with Japan Patent Office on Jul. 23, 2010, the entire contents of which are hereby incorporated by reference.

What is claimed is:

1. A method for manufacturing an SOI substrate comprising:
irradiating a single crystal semiconductor substrate with accelerated ions to form an embrittled region in the single crystal semiconductor substrate;
bonding the single crystal semiconductor substrate and a base substrate to each other with an insulating film interposed therebetween;
separating the single crystal semiconductor substrate at the embrittled region to form a first single crystal semiconductor layer over the base substrate with the insulating film interposed therebetween;
performing dry etching on the first single crystal semiconductor layer to form a second single crystal semiconductor layer having a tapered end portion; and
performing etching on the tapered end portion of the second single crystal semiconductor layer in a state where a potential on the base substrate side is a ground potential.

2. The method for manufacturing the SOI substrate, according to claim 1, wherein a mask pattern is formed over the first single crystal semiconductor layer and the dry etching and the etching in which the potential on the base substrate side is the ground potential are performed using the mask pattern.

3. The method for manufacturing the SOI substrate, according to claim 1, wherein the etching in which the potential on the base substrate side is the ground potential is performed using a gas containing chlorine, carbon tetrafluoride or a gas containing fluorine as an etching gas.

4. The method for manufacturing the SOI substrate, according to claim 1, wherein the tapered end portion of the second single crystal semiconductor layer has a taper angle greater than or equal to 30° and less than 90°.

5. The method for manufacturing the SOI substrate, according to claim 1, wherein the tapered end portion of the second single crystal semiconductor layer has a taper angle greater than or equal to 30° and less than or equal to 50°.

6. The method for manufacturing the SOI substrate, according to claim 1, wherein the dry etching is performed using a gas containing chlorine, a gas containing fluorine, trifluoromethane, hydrogen bromide, or any of these gases to which oxygen is added as an etching gas.

7. The method for manufacturing a semiconductor device using the SOI substrate according to claim 1, wherein a transistor including the second single crystal semiconductor layer is formed.

8. A method for manufacturing an SOI substrate comprising:
forming an oxide film on a surface of a single crystal semiconductor substrate;
irradiating the single crystal semiconductor substrate with accelerated ions to form an embrittled region in the single crystal semiconductor substrate with the oxide film interposed therebetween;
bonding the single crystal semiconductor substrate and a base substrate to each other with the oxide film and a nitrogen-containing layer interposed therebetween;
separating the single crystal semiconductor substrate at the embrittled region to form a first single crystal semiconductor layer over the base substrate with the oxide film and the nitrogen-containing layer interposed therebetween;
performing dry etching on the first single crystal semiconductor layer to form a second single crystal semiconductor layer having a tapered end portion; and
performing etching on the tapered end portion of the second single crystal semiconductor layer in a state where a potential on the base substrate side is a ground potential.

9. The method for manufacturing the SOI substrate, according to claim 8, wherein a mask pattern is formed over the first single crystal semiconductor layer and the dry etching and the etching in which the potential on the base substrate side is the ground potential are performed using the mask pattern.

10. The method for manufacturing the SOI substrate, according to claim 8, wherein the etching in which the potential on the base substrate side is the ground potential is performed using a gas containing chlorine, carbon tetrafluoride or a gas containing fluorine as an etching gas.

11. The method for manufacturing the SOI substrate, according to claim 8, wherein the tapered end portion of the second single crystal semiconductor layer has a taper angle greater than or equal to 30° and less than 90°.

12. The method for manufacturing the SOI substrate, according to claim 8, wherein the tapered end portion of the second single crystal semiconductor layer has a taper angle greater than or equal to 30° and less than or equal to 50°.

13. The method for manufacturing the SOI substrate, according to claim 8, wherein the dry etching is performed using a gas containing chlorine, a gas containing fluorine, trifluoromethane, hydrogen bromide, or any of these gases to which oxygen is added as an etching gas.

14. The method for manufacturing a semiconductor device using the SOI substrate according to claim 8, wherein a transistor including the second single crystal semiconductor layer is formed.
